(19) United States
(12) Patent Application Publication
(10) Pub. No.: US 2026/0255729 A1
(43) Pub. Date: Aug. 27, 2026

(54) CERAMIC SUBSTRATE, LIGHT-EMITTING DEVICE, AND METHODS FOR MANUFACTURING CERAMIC SUBSTRATE AND LIGHT-EMITTING DEVICE

(71) Applicant: NICHIA CORPORATION, Anan-shi (JP)

(72) Inventors: Takashi KAWAMATA, Tokushima-shi (JP); Akiko NAGAE, Tokushima-shi (JP); Hiroto KUME, Tokushima-shi (JP)

(73) Assignee: NICHIA CORPORATION, Anan-shi (JP)

(21) Appl. No.: 19/545,027

(22) Filed: Feb. 20, 2026

(30) Foreign Application Priority Data
Feb. 25, 2025 (JP) 2025-028392

(51) Int. Cl. H10H 20/01; H10H 20/857

(52) U.S. Cl. CPC H10H 20/0364; H10H 20/857

(57) ABSTRACT

A method for manufacturing a ceramic substrate includes preparing a ceramic plate having a first surface and a second surface on a side opposite to the first surface, and including a through hole that connects the first surface and the second surface and has a first opening formed in the first surface, and a second opening formed in the second surface. A maximum diameter of the second opening is less than 0.90 times a maximum diameter A1 of the first opening. The method further includes bringing into contact an inner surface defining the through hole of the ceramic plate and an etchant, blasting the through hole from the second surface, disposing a first conductive paste in the through hole having been subjected to the blasting, and sintering the first conductive paste.

### CROSS-REFERENCE TO RELATED APPLICATIONS

The present application claims priority under 35 U.S.C. § 119 to Japanese Patent Application No. 2025-028392, filed Feb. 25, 2025, the contents of which are incorporated herein by reference in their entirety.

### BACKGROUND

### Technical Field

The present disclosure relates to a ceramic substrate, a light-emitting device, and methods for manufacturing the ceramic substrate and the light-emitting device.

### Background Art

In recent years, a substrate has been proposed in which a through hole (also referred to as a “hole”, a “via”, or the like) is formed in an insulating substrate, and a conductive material such as copper or silver is disposed in the through hole to make both surfaces of the substrate conductive to each other, in order to achieve miniaturization, high functionality, and integration of electronic apparatuses or components.

For example, as one of the methods for forming a through hole in such an insulating substrate, there is a known method in which a through hole is formed by laser irradiation and then the inside of the through hole is plated (see Japanese Patent Publication No. S63-196094).

In addition, it is described that the opening diameter of an opening of the through hole in the insulating substrate formed by laser irradiation becomes smaller in a laser irradiation direction (see Japanese Patent Publication No. 2022-13766). That is, it is known that the through hole has a tapered shape in a cross-sectional view in a thickness direction of the insulating substrate.

Further, there is also a known method in which a through hole is fabricated in a ceramic green sheet by laser irradiation, a metal paste is filled in the through hole, and then the ceramic green sheet and the metal paste are sintered at the same time (see Japanese Patent Publication No. 2015-162575).

### SUMMARY

Embodiments of the present invention can provide a ceramic substrate, on a surface of which cracking is less likely to occur, and a light-emitting device, and to provide methods for manufacturing the ceramic substrate and the light-emitting device. In another aspect, embodiments of the present invention can provide a ceramic substrate in which a short-circuit is less likely to occur when an electronic component is mounted, and a light-emitting device, and to provide methods for manufacturing the ceramic substrate and the light-emitting device.

A method for manufacturing a ceramic substrate according to an embodiment of the present disclosure includes: preparing a ceramic plate having a first surface and a second surface on a side opposite to the first surface, the ceramic plate comprising a through hole that connects the first surface and the second surface, the through hole having a first opening formed in the first surface and a second opening formed in the second surface, a maximum diameter B1 of the second opening being less than 0.90 times a maximum diameter A1 of the first opening; bringing into contact an inner surface, defining the through hole, of the ceramic plate and an etchant; blasting the through hole from the second surface side; disposing a first conductive paste in the through hole having been subjected to the blasting; and sintering the first conductive paste.

A method for manufacturing a light-emitting device according to an embodiment of the present disclosure includes: preparing the ceramic substrate manufactured by the method for manufacturing a ceramic substrate according to present disclosure; and disposing a light-emitting element, including an electrode, on the ceramic substrate.

A ceramic substrate according to an embodiment of the present disclosure includes: a ceramic plate having a first surface and a second surface on a side opposite to the first surface, the ceramic plate including a through hole that connects the first surface and the second surface; and a conductive member disposed inside the through hole, in which C1>C2>C3 is satisfied, A2>C1 is satisfied, and B2>C3 is satisfied, where a maximum diameter of a first opening of the through hole is defined as A2, the first opening being formed in the first surface, a maximum diameter of a second opening of the through hole is defined as B2, the second opening being formed in the second surface, and an average length between the first surface and the second surface is defined as L, and where a maximum diameter of the through hole in a cross section in a direction substantially orthogonal to a thickness direction of the ceramic substrate at a location of L/4 from the first surface is defined as C1, a maximum diameter of the through hole in a cross section in a direction substantially orthogonal to the thickness direction of the ceramic substrate at a location of L/2 from the first surface is defined as C2, and a maximum diameter of the through hole in a cross section in a direction substantially orthogonal to the thickness direction of the ceramic substrate at a location of 3L/4 from the first surface is defined as C3.

A light-emitting device according to an embodiment of the present disclosure includes: the ceramic substrate according to the present disclosure; and a light-emitting element including an electrode, and disposed on the ceramic substrate.

An embodiment of the present disclosure makes it possible to provide a ceramic substrate, on a surface of which cracking is less likely to occur, and a light-emitting device, and to provide methods for manufacturing the ceramic substrate and the light-emitting device. In another aspect, it is possible to provide a ceramic substrate in which a short-circuit is less likely to occur when an electronic component is mounted, and a light-emitting device, and to provide methods for manufacturing the ceramic substrate and the light-emitting device.

### BRIEF DESCRIPTION OF DRAWINGS

FIG. 1 is a flowchart illustrating an example of a method for manufacturing a ceramic substrate according to a first embodiment.

FIG. 2A is a schematic cross-sectional view illustrating an example of a ceramic plate used in the method for manufacturing a ceramic substrate according to the first embodiment.

FIG. 2B is a schematic top view of the ceramic plate in FIG. 2A.

FIG. 2C is a schematic bottom view of the ceramic plate in FIG. 2A.

FIG. 3 is a schematic cross-sectional view illustrating an example of bringing into contact in the method for manufacturing a ceramic substrate according to the first embodiment.

FIG. 4A is a schematic cross-sectional view illustrating an example of blasting in the method for manufacturing a ceramic substrate according to the first embodiment.

FIG. 4B is a schematic cross-sectional view illustrating the size of each part in FIG. 4A.

FIG. 5A is a schematic cross-sectional view illustrating an example of disposing a first conductive paste in the method for manufacturing a ceramic substrate according to the first embodiment.

FIG. 5B is an enlarged cross-sectional view in which a region VB in FIG. 5A is enlarged and schematically illustrated.

FIG. 6A is a schematic cross-sectional view illustrating an example of sintering in the method for manufacturing a ceramic substrate according to the first embodiment.

FIG. 6B is an enlarged cross-sectional view schematically illustrating a state of a conductive member by enlarging a region VIB in FIG. 6A.

FIG. 7A is a schematic cross-sectional view illustrating an example of blasting in a method for manufacturing a ceramic substrate according to a fourth embodiment.

FIG. 7B is a schematic cross-sectional view illustrating the size of each part in FIG. 7A.

FIG. 8 is a flowchart illustrating an example of preparing a ceramic plate in a method for manufacturing a ceramic substrate according to a fifth embodiment.

FIG. 9 is a schematic cross-sectional view illustrating an example of preparing a ceramic plate not including a through hole in the method for manufacturing a ceramic substrate according to the fifth embodiment.

FIG. 10A is a schematic cross-sectional view illustrating an example of forming a through hole in the method for manufacturing a ceramic substrate according to the fifth embodiment.

FIG. 10B is a schematic top view of a ceramic plate in FIG. 10A.

FIG. 10C is a schematic bottom view of the ceramic plate in FIG. 10A.

FIG. 11A is a schematic cross-sectional view illustrating an example of a case of using an etchant containing an alkaline solution in bringing into contact in the method for manufacturing a ceramic substrate according to the fifth embodiment.

FIG. 11B is a schematic cross-sectional view illustrating an example of a case of using an etchant containing an acid solution in bringing into contact in the method for manufacturing a ceramic substrate according to the fifth embodiment.

FIG. 12 is a flowchart illustrating an example of preparing a ceramic plate in a method for manufacturing a ceramic substrate according to a sixth embodiment.

FIG. 13A is a schematic cross-sectional view illustrating an example of disposing a first covering member and a second covering member in the method for manufacturing a ceramic substrate according to the sixth embodiment.

FIG. 13B is a schematic cross-sectional view illustrating an example of disposing a second conductive paste in the method for manufacturing a ceramic substrate according to the sixth embodiment.

FIG. 14 is a schematic cross-sectional view illustrating an example of sintering in the method for manufacturing a ceramic substrate according to the sixth embodiment.

FIG. 15 is a flowchart illustrating an example of preparing a ceramic plate in a method for manufacturing a ceramic substrate according to a seventh embodiment.

FIG. 16A is a schematic cross-sectional view illustrating an example of polishing or grinding in the method for manufacturing a ceramic substrate according to the seventh embodiment.

FIG. 16B is a schematic cross-sectional view illustrating an example of a ceramic substrate after having been polished or ground in the method for manufacturing a ceramic substrate according to the seventh embodiment.

FIG. 16C is a schematic cross-sectional view illustrating another example of a ceramic substrate after having been polished or ground in the method for manufacturing a ceramic substrate according to the seventh embodiment, in the method for manufacturing a ceramic substrate according to the fourth embodiment.

FIG. 17A is a schematic cross-sectional view illustrating an example of a ceramic substrate according to an eighth embodiment.

FIG. 17B is a schematic top view of the ceramic substrate in FIG. 17A.

FIG. 17C is a schematic cross-sectional view in a direction substantially orthogonal to a thickness direction of the ceramic substrate at a location L1 of the ceramic substrate in FIG. 17A.

FIG. 17D is a schematic cross-sectional view in a direction substantially orthogonal to the thickness direction of the ceramic substrate at a location L2 of the ceramic substrate in FIG. 17A.

FIG. 17E is a schematic cross-sectional view in a direction substantially orthogonal to the thickness direction of the ceramic substrate at a location L3 of the ceramic substrate in FIG. 17A.

FIG. 17F is a schematic cross-sectional view in a direction substantially orthogonal to the thickness direction of the ceramic substrate at a location where the maximum diameter of a through hole in a cross section in the direction substantially orthogonal to the thickness direction of the ceramic substrate is smallest between a second surface of the ceramic substrate in FIG. 17A and the location L3.

FIG. 17G is a schematic bottom view of the ceramic substrate in FIG. 17A.

FIG. 17H is an enlarged view of a region XVIIH in FIG. 17A.

FIG. 18A is a schematic cross-sectional view illustrating an example of a ceramic substrate according to a ninth embodiment.

FIG. 18B is an enlarged view of a region XVIIIB in FIG. 18A.

FIG. 19 is a schematic cross-sectional view illustrating an example of a light-emitting device according to an embodiment.

FIG. 20A is a perspective view illustrating an application example of the light-emitting device according to the embodiment.

FIG. 20B is a cross-sectional view taken along a line XXB-XXB in FIG. 20A.

FIG. 21 is a flowchart illustrating an example of a method for manufacturing the light-emitting device according to the embodiment.

FIG. 22A is a SEM cross-sectional observation image of a through hole 2 observed at a magnification of 500 after having undergone S32 of bringing into contact in Example 1.

FIG. 22B is a SEM cross-sectional observation image depicting the entirety of a ceramic plate 1 after having undergone S32 of bringing into contact in Example 1.

FIG. 23A is a SEM cross-sectional observation image of the through hole 2 observed at a magnification of 500 after having undergone S33 of blasting in Example 1.

FIG. 23B is a SEM cross-sectional observation image depicting the entirety of the ceramic plate 1 after having undergone S33 of blasting in Example 1.

FIG. 23C is a partially enlarged image of a SEM cross-sectional observation image of the through hole 2 after having undergone S33 of blasting in Example 1.

FIG. 23D is a partially enlarged image of a focused ion beam-SEM (FIB-SEM) cross-sectional observation image of the through hole 2 after having undergone S33 of blasting in Example 1.

FIG. 24A is a top view of a design drawing of the ceramic plate 1.

FIG. 24B is a table depicting simulation condition values of a component number (1) and a component number (2) in FIG. 24A.

FIG. 24C is a cross-sectional view taken along a line XXIVCD-XXIVCD in FIG. 24A based on “Design 1”.

FIG. 24D is a cross-sectional view taken along the line XXIVCD-XXIVCD in FIG. 24A based on “Design 2”.

FIG. 24E is an enlarged cross-sectional view of a region XXIVE in FIG. 24D.

FIG. 24F is a graph depicting a temperature condition of simulation.

FIG. 25A is a simulation result of stress in a top view of the ceramic plate 1 based on “Design 1”.

FIG. 25B is a simulation result of stress in a cross-sectional view of the ceramic plate 1 based on “Design 1”.

FIG. 25C is a simulation result of stress in a cross-sectional view of the ceramic plate 1 based on “Design 2”.

### DETAILED DESCRIPTION

A ceramic substrate, a light-emitting device, and methods for manufacturing the ceramic substrate and the light-emitting device according to embodiments of the present disclosure will be described in detail with reference to the drawings. However, forms to be described below are examples of a ceramic substrate, a light-emitting device, and methods for manufacturing the ceramic substrate and the light-emitting device for embodying the technical idea of the present disclosure, and the forms are not limited to those described below.

Dimensions, materials, shapes, relative arrangements, and the like of the constituent members described in the embodiments are not intended to limit the scope of the present disclosure thereto unless otherwise specified, and are merely exemplary. Note that the sizes, positional relationships, and the like of members illustrated in the drawings may be exaggerated to clarify the description. In the following description, members having the same name and reference sign indicate the same member or members of the same quality, and detailed description thereof is omitted as appropriate. Further, in order to suppress a situation where drawings become too complicated, schematic views omitting some elements may be used, or end views illustrating only cut surfaces may be used as cross-sectional views, for example.

In the present disclosure, as for polygons such as rectangles, triangles, and quadrangles, such a shape that a corner of a polygon is rounded, chamfered, beveled, or round-chamfered is also referred to as a polygon. Not only a shape in which a corner (an end of a side) is processed, but also a shape in which an intermediate portion of a side is processed is similarly referred to as a polygon. That is, a shape that is partially processed while leaving the shape based on a polygonal shape is included in the interpretation of the term “polygon” described in the present disclosure.

The same applies not only to polygons, but also to terms expressing specific shapes such as a trapezoid, a circle, and irregularities. The same applies to a case of treating each side forming the shapes. That is, even when processing has been performed on a corner or an intermediate portion of a certain side, the interpretation of “side” includes the processed portion. When a “polygon”, “side”, or the like not partially processed is to be distinguished from a processed shape, the term “strict” is added to the description as an expression of “strict quadrangle”, for example.

In the following description, terms indicating specific directions or positions (e.g., “upper”, “lower”, “lateral”, “upper surface”, “lower surface”, “lateral surface”, “X”, “Y”, “Z”, and other terms including these terms) are used as necessary. However, the above-mentioned terms are used to facilitate understanding of the invention with reference to the drawings, and the technical scope of the present invention is not excessively limited by the meanings of the above-mentioned terms. For example, the description of the term “upper surface” does not necessarily imply that the invention should be used in such a manner as to always face upward. In the embodiments, the expression “covering” includes not only a case of covering in a direct contact but also a case of covering in an indirect contact through another member, for example.

In each drawing, a Z-axis direction is defined as a thickness direction of a ceramic plate 1 or a ceramic substrate 100, a direction substantially orthogonal to the Z-axis direction is defined as an X-axis direction, and a direction substantially orthogonal to the Z-axis direction and the X-axis direction is defined as a Y-axis direction. The X-axis, the Y-axis, and the Z-axis are orthogonal to one another.

In the present specification or the claims, when a plurality of certain constituent elements are provided and these constituent elements are to be denoted individually, the constituent elements may be distinguished by adding terms such as “first”, “second”, and the like to the fronts of terms of the constituent elements.

Method for Manufacturing Ceramic Substrate

### First Embodiment

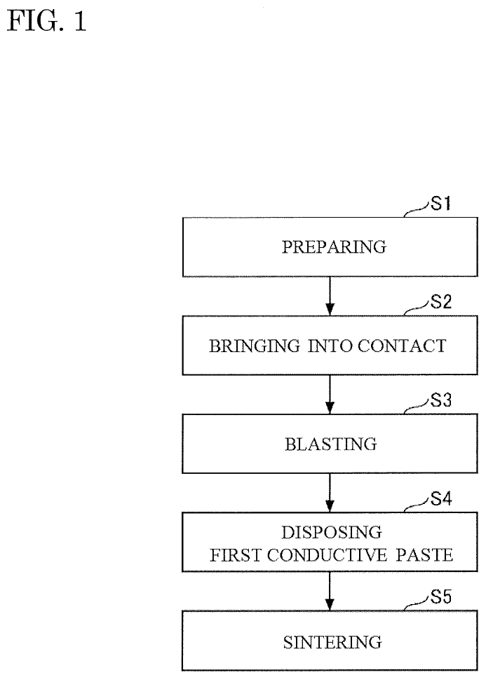

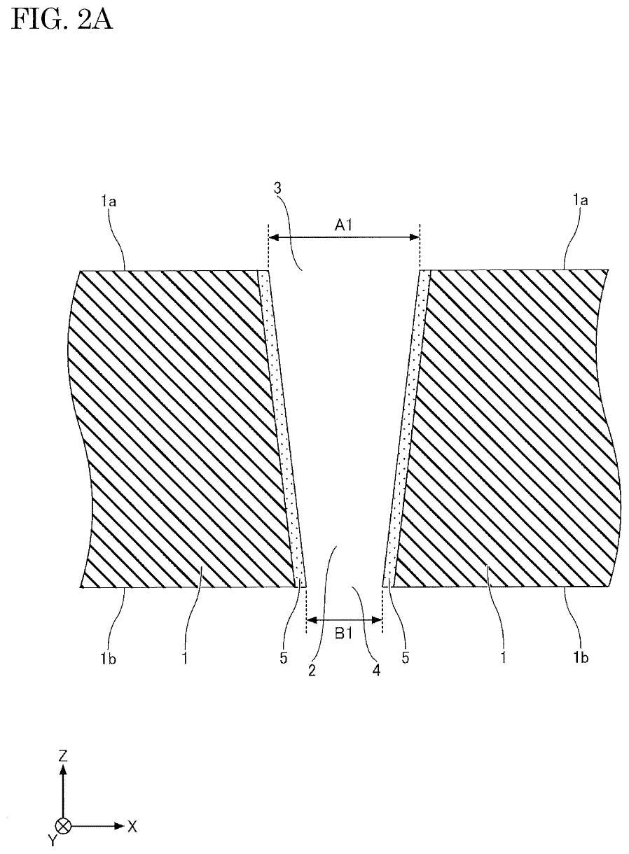

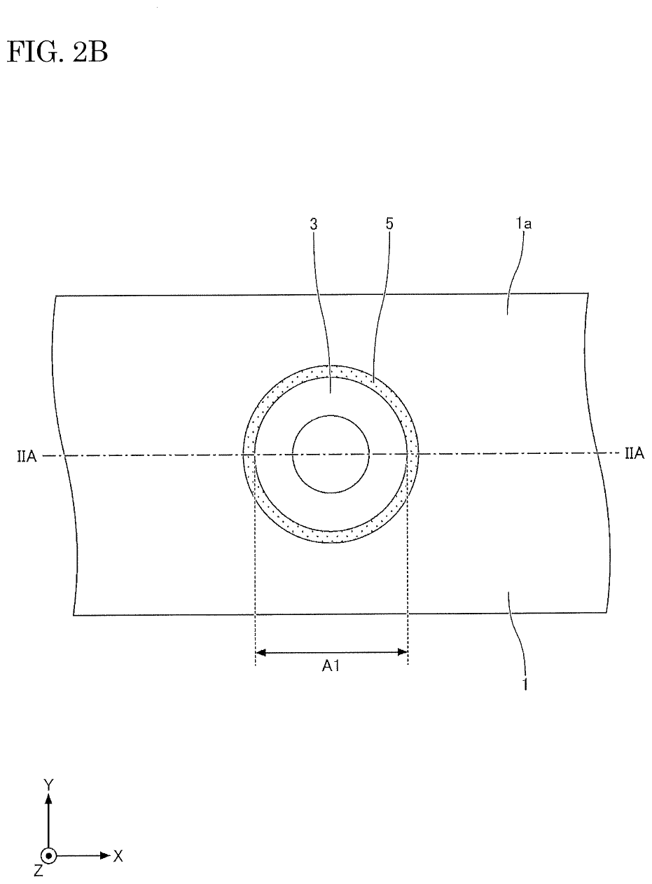

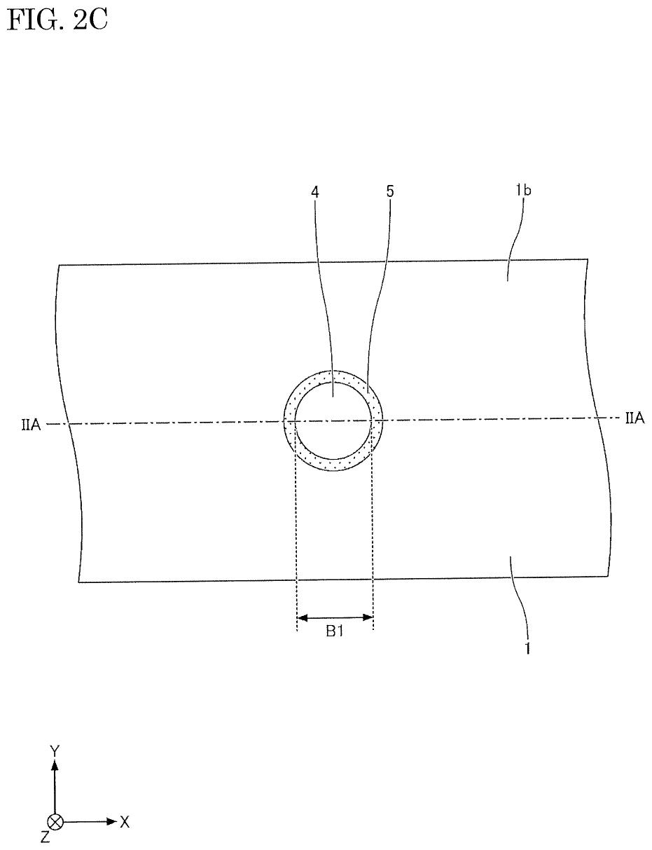

FIG. 1 is a flowchart illustrating an example of a method for manufacturing a ceramic substrate according to a first embodiment. The method for manufacturing a ceramic substrate according to the first embodiment will be described with reference to FIGS. 2A to 6B. Although the method for manufacturing one ceramic substrate 100 will be described herein, a plurality of the ceramic substrates 100 can be manufactured at the same time.

The method for manufacturing the ceramic substrate 100 according to the first embodiment includes: preparing a ceramic plate 1 having a first surface 1a and a second surface 1b on a side opposite to the first surface 1a, the ceramic plate 1 including a through hole 2 that connects the first surface 1a and the second surface 1b, the through hole 2 having a first opening 3 formed in the first surface 1a and a second opening 4 formed in the second surface 1b, a maximum diameter B1 of the second opening 4 being less than 0.90 times a maximum diameter A1 of the first opening 3; bringing into contact an inner surface defining the through hole 2 of the ceramic plate 1 and an etchant; blasting the through hole 2 from the second surface 1b; disposing a first conductive paste 6 in the through hole 2 having been subjected to the blasting; and sintering the first conductive paste 6. The method for manufacturing the ceramic substrate can further include other treatments as necessary.

In the method for manufacturing the ceramic substrate, a mode in which a first etchant contains an alkaline solution will be described. In this case, the first etchant does not contain an acid solution.

FIG. 2A is a schematic cross-sectional view illustrating an example of the ceramic plate used in the method for manufacturing the ceramic substrate according to the first embodiment. FIG. 2B is a schematic top view of the ceramic plate in FIG. 2A. FIG. 2C is a schematic bottom view of the ceramic plate in FIG. 2A. FIG. 2A is a schematic cross-sectional view taken along a line IIA-IIA in FIGS. 2B and 2C.

In S1 of preparing the ceramic plate 1, the ceramic plate 1 having the first surface 1a and the second surface 1b on the side opposite to the first surface 1a, and including the through hole 2 that connects the first surface 1a and the second surface 1b is prepared, where the maximum diameter B1 of the second opening 4 of the through hole 2 formed in the second surface 1b is less than 0.90 times the maximum diameter A1 of the first opening 3 of the through hole 2 formed in the first surface 1a. That is, B1/A1<0.90 is satisfied.

### (S1) Preparing Ceramic Plate 1

The ceramic plate 1 is an insulating member. The ceramic plate 1 can be an unsintered ceramic precursor in a softened state, or can be a sintered ceramic. However, the ceramic plate 1 is preferably a sintered ceramic in that dimensional change due to sintering does not occur, allowing the through hole 2 to be accurately formed at a desired position, and the size of the through hole 2 can be adjusted to a predetermined desired size.

The material of the ceramic plate 1 is not particularly limited, and can be appropriately selected in accordance with the purpose.

However, the ceramic plate 1 preferably includes aluminum nitride (AlN) as a main material, and can further include other auxiliary materials as necessary. Here, the term “main material” refers to a material having the largest substance amount among the materials making up the ceramic plate 1. As a material of the ceramic plate 1 other than aluminum nitride, for example, silicon nitride (Si₃N₄), aluminum oxide (Al₂O₃), or silicon carbide (SiC) can be used, but white aluminum nitride and silicon nitride having high heat resistance, high light resistance, and high thermal conductivity are preferable. As the ceramic plate 1, a commercially available product can be used.

Examples of the auxiliary materials in the ceramic plate 1 include, but are not particularly limited to, glass and ceramics other than aluminum nitride. One type of material among these materials can be used alone, or two or more types of materials can be used in combination.

Ceramics other than aluminum nitride are not particularly limited, and examples thereof include nitride-based ceramics such as silicon nitride and boron nitride; oxide-based ceramics such as aluminum oxide, silicon oxide, calcium oxide, and magnesium oxide; silicon carbide; mullite; and borosilicate glass. One type of material among these materials can be used alone, or two or more types of materials can be used in combination.

The ceramic plate 1 is preferably a plate-shaped member having a rectangular outer shape in a plan view. This rectangular shape can be a rectangular shape with long sides and short sides. The rectangular shape can include a square shape unless specifically described as excluding a square shape. The outer shape of the ceramic plate 1 in a plan view is not limited to a rectangle, and can be a circle, an ellipse, a polygon, or the like.

The first surface 1a may or may not be a flat surface. However, when the ceramic substrate 100 is used in a light-emitting device, the first surface 1a is preferably a flat surface because a light-emitting element can be suitably disposed.

The second surface 1b is a surface on the side opposite to the first surface 1a of the ceramic plate 1. The second surface 1b may or may not be a flat surface. However, when the ceramic substrate 100 is used in a light-emitting device, the second surface 1b is preferably a flat surface because the ceramic substrate 100 can be suitably disposed on a mounting substrate.

In FIG. 2A, a surface of the ceramic plate 1 on the upper side in the Z-axis direction is denoted as the first surface 1a, and a surface of the ceramic plate 1 on the lower side in the Z-axis direction is denoted as the second surface 1b; however, the first surface 1a and the second surface 1b are denoted separately only for convenience, and when the ceramic substrate 100 is used in a light-emitting device, a mounting substrate can be disposed on the first surface 1a and a light-emitting element can be disposed on the second surface 1b.

The first surface 1a and the second surface 1b are parallel to each other, for example. Herein, when the surfaces of the ceramic plate 1 are described as being “parallel”, an allowable difference is within ±5 degrees.

The through hole 2 connects the first surface 1a and the second surface 1b. The through hole 2 is, for example, a via hole.

The shape of the first opening 3 of the through hole 2 formed in the first surface 1a, and the shape of the second opening 4 of the through hole 2 formed in the second surface 1b in a plan view of the ceramic plate 1 are preferably a circular or elliptical shapes. The shapes of the first opening 3 and second opening 4 of the through hole 2 in the plan view of the ceramic plate 1 are not limited to a circular shape or an elliptical shape, and can be a polygonal shape including a rectangular shape.

The maximum diameter A1 of the first opening 3 of the through hole 2 formed in the first surface 1a, and the maximum diameter B1 of the second opening 4 of the through hole 2 formed in the second surface 1b in a plan view of the ceramic plate 1 are not particularly limited, and can be appropriately selected in accordance with the purpose, as long as the maximum diameter B1 of the second opening 4 of the through hole formed in the second surface 1b is less than 0.90 times the maximum diameter A1 of the first opening 3. For example, the maximum diameter A1 of the first opening 3 is preferably in a range of 110 μm to 150 μm, and more preferably in a range of 125 μm to 135 μm. For example, the maximum diameter B1 of the second opening 4 is preferably in a range of 60 μm to 90 μm, and more preferably in a range of 65 μm to 75 μm.

When the first opening 3 and the second opening 4 of the through hole 2 are both formed in a circular shape, the “maximum diameter A1” and the “maximum diameter B1” are the diameters of the first opening 3 and the second opening 4, respectively. When the first opening 3 and the second opening 4 of the through hole 2 are both formed in an elliptical shape, the “maximum diameter A1” and the “maximum diameter B1” are the major axes of the first opening 3 and the second opening 4, respectively. When the first opening 3 and the second opening 4 of the through hole 2 are both formed in a rectangular shape in a plan view of the ceramic plate 1, the “maximum diameter A1” and the “maximum diameter B1” are respectively the maximum lengths of the diagonal lines of the first opening 3 and the second opening 4.

The number of through holes 2 in the ceramic plate 1 is not particularly limited, and can be one or more than one, but is preferably more than one considering mounting the ceramic plate 1 in a light-emitting device.

The inner surface of the through hole 2 includes a damaged layer 5 produced due to the inner surface of the through hole 2 being damaged during the processing for forming the through hole 2. The damaged layer 5 can include a crack or become brittle. In the present disclosure, the damaged layer 5 refers to a region in the ceramic plate 1 in which a deterioration such as a crack and/or reduction in strength has occurred.

(S2) Bringing into Contact

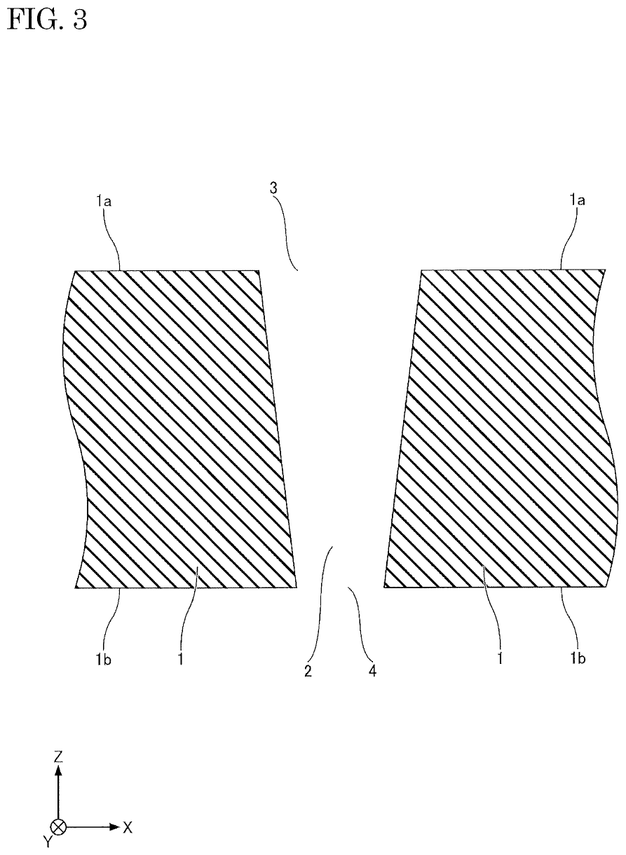

FIG. 3 is a schematic cross-sectional view illustrating an example of bringing into contact in the method for manufacturing a ceramic substrate according to the first embodiment.

In S2 of bringing into contact, the inner surface defining the through hole 2 of the ceramic plate 1 and an etchant are brought into contact with each other. At this time, the damaged layer 5 disposed on the inner surface of the through hole 2 and the etchant come into contact with each other. This makes it possible to remove the damaged layer 5 in S2 of bringing into contact. In the method for manufacturing a ceramic substrate according to the first embodiment, the etchant contains an alkaline solution.

Examples of the etchant containing an alkaline solution include an etchant containing, as a pH adjusting agent, one or more compounds selected from the group consisting of potassium hydroxide, sodium hydroxide, lithium hydroxide, calcium hydroxide, and magnesium hydroxide.

The concentration of the pH adjusting agent contained in the alkaline solution-containing etchant is not particularly limited as long as the damaged layer 5 can be removed, and can be appropriately selected in accordance with the purpose, but is preferably in a range of 1.5 mol/L to 3.5 mol/L, and more preferably in a range of 2.5 mol/L to 3.5 mol/L. When the concentration of the pH adjusting agent contained in the alkaline solution-containing etchant is 1.5 mol/L or more, the inner surface of the ceramic plate 1 defining the through hole 2 can be efficiently etched, and the damaged layer 5 can be removed. When the concentration of the pH adjusting agent contained in the alkaline solution-containing etchant is 3.5 mol/L or less, the etching rate of the ceramic plate 1 does not become excessively high, so that the opening diameter and the shape of the through holes 2 are easily adjusted to the desired ones.

The method of bringing the inner surface defining the through hole 2 of the ceramic plate 1 into contact with the etchant containing the alkaline solution is not particularly limited, and can be appropriately selected in accordance with the purpose. Examples of the method include a method in which the ceramic plate 1 having the through hole 2 is immersed in the alkaline solution-containing etchant, and a method in which the alkaline solution-containing etchant is supplied to the ceramic plate 1 so that the first surface 1a, the second surface 1b, and the inside of the through holes 2 of the ceramic plate 1 are brought into contact with the etchant. Among them, as a method of bringing the inner surface defining the through hole 2 of the ceramic plate 1 into contact with the etchant containing the alkaline solution, the method in which the ceramic plate 1 having the through hole 2 is immersed in the alkaline solution-containing etchant is efficient and preferable.

In S2 of bringing into contact, the temperature at which the etchant containing the alkaline solution and the inner surface defining the through hole 2 of the ceramic plate 1 are brought into contact with each other is not particularly limited as long as the damaged layer 5 can be removed, and can be appropriately selected in accordance with the purpose, but is preferably 50° C. or higher and lower than 100° C., and more preferably 70° C. or higher and 95° C. or lower. When the temperature at which the etchant containing the alkaline solution and the inner surface defining the through hole 2 of the ceramic plate 1 are brought into contact with each other is 50° C. or higher, the inner surface defining the through hole 2 of the ceramic plate 1 can be efficiently etched. When the temperature at which the etchant containing the alkaline solution and the inner surface defining the through hole 2 of the ceramic plate 1 are brought into contact with each other is lower than 100° C., it is possible to prevent the etchant containing the alkaline solution from boiling.

In S2 of bringing into contact, the period of time during which the etchant containing the alkaline solution and the inner surface defining the through hole 2 of the ceramic plate 1 are brought into contact with each other is not particularly limited as long as the damaged layer 5 can be removed, and can be appropriately selected in accordance with the purpose, but is preferably in a range of 5 minutes to 60 minutes. When the period of time during which the etchant containing the alkaline solution and the inner surface defining the through hole 2 of the ceramic plate 1 are brought into contact with each other is 60 minutes or longer, the inner surface defining the through hole 2 of the ceramic plate 1 can be efficiently etched and the damaged layer 5 can be removed. When the period of time during which the etchant containing the alkaline solution and the inner surface defining the through hole 2 of the ceramic plate 1 are brought into contact with each other is 180 minutes or shorter, the opening diameter and the shape of the through hole 2 are easily adjusted to the desired ones, and it is possible to prevent the thickness of the ceramic plate 1 from being reduced by etching.

In S2 of bringing into contact, the atmosphere conditions under which the alkaline solution-containing etchant and the inner surface defining the through hole 2 of the ceramic plate 1 are brought into contact with each other are not particularly limited, and S2 of bringing into contact can be performed under atmospheric conditions.

Among them, in S2 of bringing into contact, the contact is made preferably for 5 minutes or more and 60 minutes or less under an atmospheric condition of temperature lower than 100° C., and more preferably for 10 minutes or more and 30 minutes or less under an atmospheric condition of temperature equal to or higher than 70° C. and lower than 100° C.

### S3 Blasting

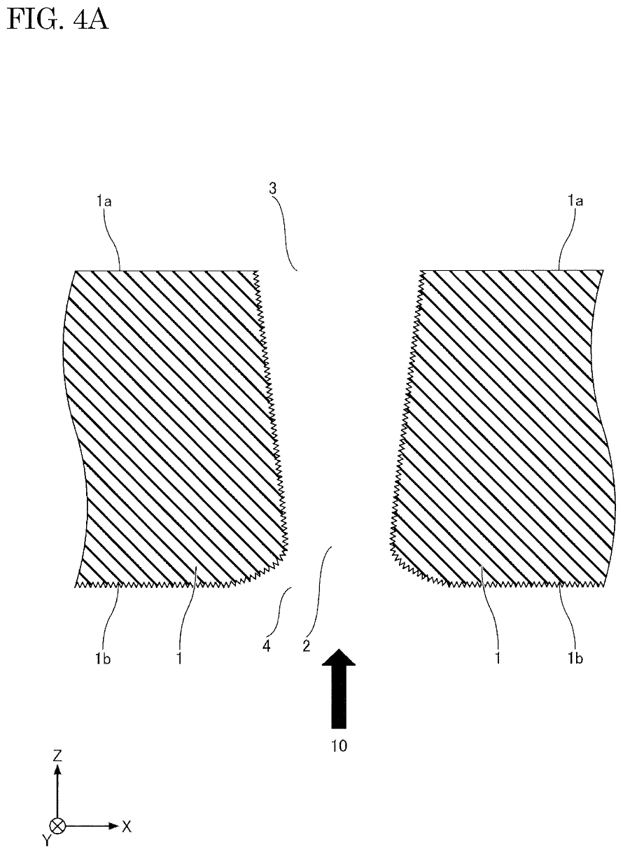

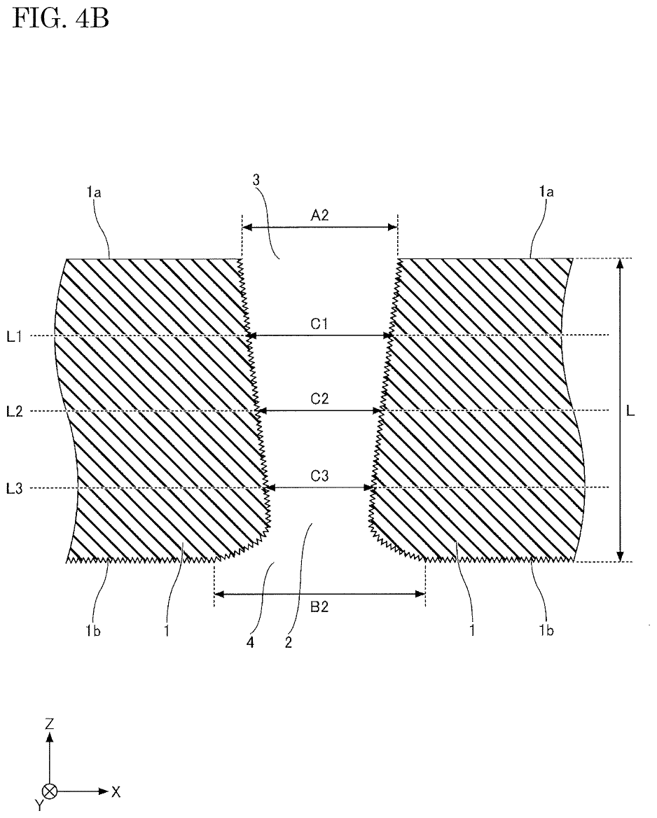

FIGS. 4A and 4B are schematic cross-sectional views illustrating an example of blasting in the method for manufacturing a ceramic substrate according to the first embodiment. FIG. 4B is a schematic cross-sectional view illustrating the size of each part in FIG. 4A.

In S3 of blasting, an abrasive 10 is applied from the second surface 1b side to cause the through hole 2 to be subjected to blasting. By performing this blasting, the ceramic plate 1 defining the second opening 4 is shaved at the second opening 4 of the through hole 2 formed in the second surface 1b. In addition, the surface of the second surface 1b and the surface of the inner surface of the through hole 2 are roughened.

By performing S3 of blasting, C1>C2>C3 is satisfied, A2>C1 is satisfied, and B2>C3 is satisfied, where a maximum diameter of the first opening 3 of the through hole 2 is defined as A2, the first opening 3 being formed in the first surface 1a, a maximum diameter of the second opening 4 of the through hole 2 is defined as B2, the second opening 4 being formed in the second surface 1b, and an average length between the first surface 1a and the second surface 1b is defined as L, and where a maximum diameter of the through hole 2 in a cross section in a direction substantially orthogonal to the thickness direction of the ceramic plate 1 at a location of L/4 from the first surface 1a, that is, at a location L1, is defined as C1, a maximum diameter of the through hole 2 in a cross section in the direction substantially orthogonal to the thickness direction of the ceramic plate 1 at a location of L/2 from the first surface 1a, that is, at a location L2, is defined as C2, and a maximum diameter of the through hole 2 in a cross section in the direction substantially orthogonal to the thickness direction of the ceramic plate 1 at a location of 3L/4 from the first surface 1a, that is, at a location L3, is defined as C3. In this case, A2<B2 is satisfied. This allows a pitch distance between the adjacent through holes 2 on the first surface 1a side to be smaller than a pitch distance between the adjacent through holes 2 on the second surface 1b side, allowing for enhancing the degree of freedom in designing for mounting of the light-emitting elements and the like. Further, by increasing the opening area of B2, thermal conductivity toward the second surface 1b can be increased.

By performing S2 of bringing into contact and S3 of blasting, the maximum diameter B2 of the second opening 4 of the through hole 2 formed in the second surface 1b is larger than the initial maximum diameter B1 of the second opening 4 in a plan view of the ceramic plate 1 by at least 10 μm, and in some cases, by 200 μm or more.

Preferably, the through hole 2 has, in the vicinity of the second opening 4 in the second surface 1b, a tapered shape in which the opening diameter decreases from the second surface 1b gradually in the thickness direction of the ceramic plate 1 in a cross-sectional view.

In S3 of blasting, the type of abrasive 10 is not particularly limited, and can be appropriately selected from known abrasives.

The method of blasting in S3 of blasting is not particularly limited, and can be a dry blasting method or a wet blasting method.

In S3 of blasting, an arithmetic mean roughness Ra of the inner surface defining the through hole 2 is not particularly limited, and can be appropriately selected in accordance with the purpose, but is preferably in a range of 0.5 μm to 2.0 μm. The arithmetic mean roughness Ra of the inner surface defining the through hole 2 is measured in compliance with JIS B 0601 by using a stylus type surface roughness measuring instrument (for example, SE 3500 manufactured by Kosaka Laboratory Ltd.) equipped with a diamond stylus having a tip curvature radius r of 2 μm.

### (S4) Disposing First Conductive Paste

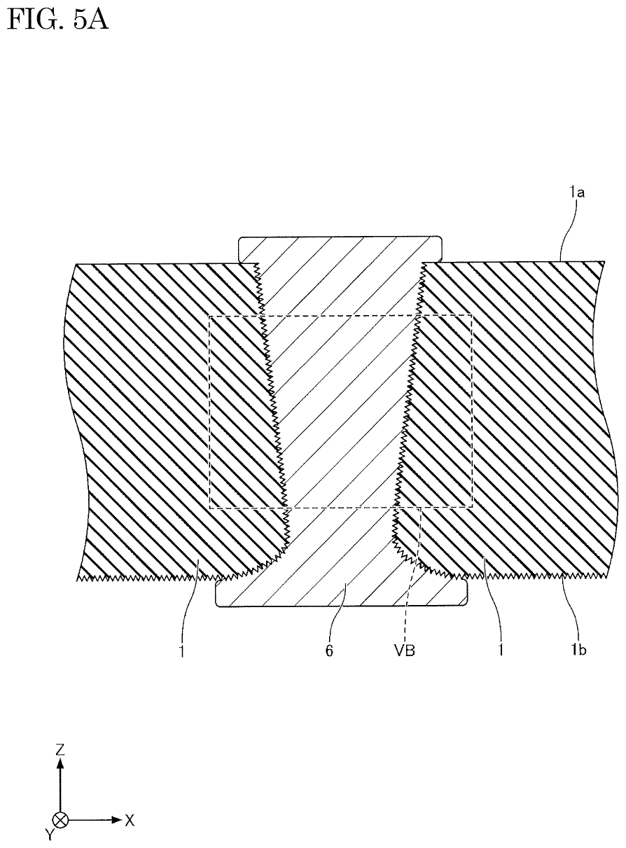

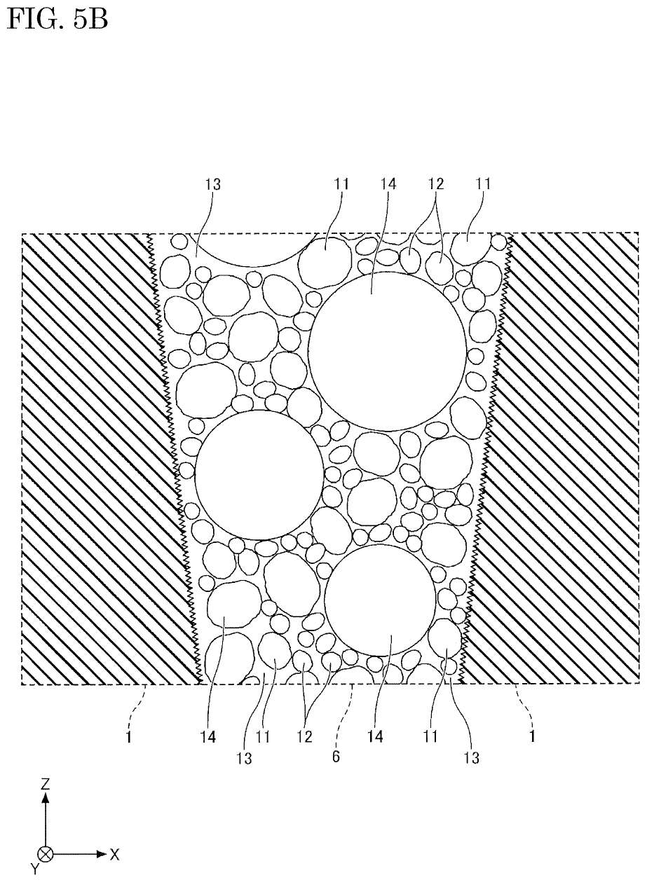

FIG. 5A is a schematic cross-sectional view illustrating an example of disposing a first conductive paste in the method for manufacturing a ceramic substrate according to the first embodiment. FIG. 5B is an enlarged cross-sectional view in which a region VB in FIG. 5A is enlarged and schematically illustrated.

In S4 of disposing a first conductive paste, a first conductive paste 6 is disposed in the through hole 2 having been blasted.

In S4 of disposing a first conductive paste, the first conductive paste 6 can be disposed by filling the through hole 2 with the first conductive paste 6 by, for example, screen printing, metal mask printing, or injection using a nozzle such that a surface of the paste is substantially flush with the first surface 1a and the second surface 1b of the ceramic plate 1.

In S4 of disposing a first conductive paste, in addition to filling the through hole 2 with the first conductive paste 6, the first conductive paste 6 is preferably disposed to cover the first opening 3 and the second opening 4 of the through hole 2, and at least a part of at least one of the first surface 1a and the second surface 1b of the ceramic plate 1. This can hinder a decrease in dimensional accuracy due to volume shrinkage when the first conductive paste 6 is sintered in S5 of sintering, so that a first conductive member 7a can have a sufficient thickness.

As a specific example, when the through hole 2 is filled with the first conductive paste 6 in S4 of disposing a first conductive paste, the through hole 2 is filled with the first conductive paste 6 from the first surface 1a of the ceramic plate 1 by using, for example, a squeegee as a tool used for screen printing, and further the through hole 2 is filled with the first conductive paste 6 from the second surface 1b of the ceramic plate 1 by using the squeegee in a manner similar to that of the first surface 1a, allowing the first conductive paste 6 to be disposed to cover the first opening 3 and the second opening 4 of the through hole 2 and at least a part of at least one of the first surface 1a and the second surface 1b of the ceramic plate 1. That is, the first conductive paste 6 can be disposed covering at least a part of at least one of the first surface 1a and the second surface 1b of the ceramic plate 1 continuously from the through hole 2.

In S4 of disposing a first conductive paste, after disposing the first conductive paste 6 and before sintering, it is preferable to additionally dry the first conductive paste 6, and pressurize the dried first conductive paste 6. In order to dry the first conductive paste 6, the first conductive paste 6 can be set in an electric furnace having an atmosphere at a temperature higher than room temperature and lower than 100° C., for example. It is preferable that the ceramic plate 1 with the first conductive paste 6 is placed in the electric furnace together with a mold for pressing, allowing pressing and drying to be performed simultaneously. In this case, by drying and pressing the first conductive paste 6, the volume shrinkage of the first conductive paste 6 is less likely to occur in S5 of sintering. In the thickness direction of the ceramic plate 1, the first conductive paste 6 is preferably disposed to protrude outward of the ceramic plate 1. Because the first conductive paste 6 is likely to shrink in volume when sintered, a sink mark is likely to be generated on the surface of the first conductive member 7a. Accordingly, when the through hole 2 is filled with the first conductive paste 6 to a height at which a surface of the first conductive paste 6 is flush with a surface of the ceramic plate 1, the first conductive member 7a can be recessed relative to the first surface 1a of the ceramic plate 1, and thus it is difficult for the first conductive member 7a and the first surface 1a of the ceramic plate 1 to be flush with each other.

### First Conductive Paste 6

The first conductive paste 6 preferably includes an active metal brazing material in terms of suitably forming a nitride coating film 16b on the inner surface defining the through hole 2, and improving the adhesion between the ceramic plate 1 and the first conductive member 7a. The active metal brazing material contains a eutectic powder 11 of silver and copper, an active metal powder 12, and a solvent 13, preferably further contains an inorganic filler 14, and further contains other components as necessary.

The active metal brazing material has fluidity, can freely fill the through hole 2 having an optional shape, and can be disposed by being cured after being applied in an optional shape and with an optional thickness.

### Eutectic Powder 11

The eutectic powder 11 is a eutectic powder of silver and copper. The melting point of the eutectic powder of silver and copper is about 780° C.

The content of the eutectic powder 11 in the first conductive paste 6 is not particularly limited, but is preferably in a range of 40 mass % to 95 mass % when the total amount of the eutectic powder 11, the active metal powder 12, and the inorganic filler 14 is 100 mass %.

### Active Metal Powder 12

The active metal powder 12, after sintering, becomes a metal compound 16 located on the inner surface defining the through hole 2 and on at least a part of the surface of the inorganic filler 14.

The active metal powder 12 contains, for example, but is not particularly limited to, titanium hydride (TiH₂), cerium hydride (CeH₂), zirconium hydride (ZrH₂), or magnesium hydride (MgH₂). One type of material among these materials can be used alone, or two or more types of these materials can be used in combination. Among these, the active metal powder 12 preferably contains titanium hydride. When the active metal powder 12 contains titanium hydride, and in a case in which aluminum nitride is exposed on the inner surface defining the through hole 2, the active metal powder 12 reacts with the aluminum nitride and can become titanium nitride (TiN) as the metal compound 16. Titanium nitride is known as a barrier metal. Accordingly, the migration of the metal in the first conductive member 7a can be reduced, and the ceramic substrate 100 having high reliability can be obtained.

The content of the active metal powder 12 in the first conductive paste 6 is not particularly limited, but is preferably in a range of 2 mass % to 15 mass % when the total amount of the eutectic powder 11, the active metal powder 12, and the inorganic filler 14 is 100 mass %. When the content of the active metal powder 12 is 2 mass % or more relative to the total amount of the eutectic powder 11, the active metal powder 12, and the inorganic filler 14, the nitride coating film 16b having an appropriate thickness can be formed. In addition, hydrogen derived from the active metal powder 12 can bring a reaction phase into a reducing atmosphere, so that the first conductive paste 6 can be appropriately sintered. This is because when the content of the active metal powder 12 is not greater than 15 mass % relative to the total amount of the eutectic powder 11, the active metal powder 12, and the inorganic filler 14, it is possible to lower the possibility that the generated hydrogen is not sufficiently released and remains as a void in the first conductive member 7a.

### Solvent 13

The solvent 13 is not particularly limited, but is preferably an organic binder. The organic binder is not particularly limited, and examples thereof include a thermosetting resin and a thermoplastic resin. Specific examples of the organic binder include epoxy resins, silicone resins, acrylic resins, urethane resins, polyvinyl resins, ethyl cellulose resins, phenol resins, polyimide resins, polyurethane resins, melamine resins, and polyurea resins. The organic binder can be a solvent and a resin material generally used as a via material. One type of material among these materials can be used alone, or two or more types of materials can be used in combination. Since the organic binder serves as a binder for sintering, the organic binder is decomposed, evaporated, and removed in S5 of sintering.

The content of the solvent 13 in the first conductive paste 6 is not particularly limited, and can be appropriately selected depending on the content of the eutectic powder 11, the active metal powder 12, and the inorganic filler 14. The content of the solvent 13 can be in a range of 0.5 mass % to 20 mass %, preferably in a range of 1 mass % to 15 mass %, and more preferably in a range of 2 mass % to 10 mass %.

### Inorganic Filler 14

The inorganic filler 14 is not particularly limited, and examples thereof include ceramic fillers such as silica fillers, metal fillers, and glass fillers. One type of material among these materials can be used alone, or two or more types of materials can be used in combination. Among these materials, the ceramic filler is preferable as the inorganic filler 14. When the first conductive paste 6 includes the inorganic filler 14, the thermal conductivity and the heat dissipation property of the first conductive member 7a can be improved.

The ceramic filler is not particularly limited, and examples thereof include aluminum nitride (AlN), silicon nitride (Si₃N₄), aluminum oxide (Al₂O₃), and silicon carbide (SiC).

The inorganic filler 14 is preferably a material having a linear expansion coefficient of 8 ppm or less. With this material, the linear coefficient of the first conductive member 7a can be lowered, and thermal shock characteristics can be improved.

The median diameter of the inorganic filler 14 is not particularly limited, but is preferably in a range of 1 μm to 50 μm, and more preferably in a range of 2 μm to 15 μm.

The inorganic filler 14 is preferably a material having a linear expansion coefficient of 5 ppm or less and a high thermal conductivity of 100 W/m·K or more. Examples of such a material include the ceramic filler described above. By dispersing and disposing such a material in the first conductive member 7a, a difference in linear expansion coefficient can be reduced and reliability such as thermal shock characteristics can be improved.

The thermal conductivity of the inorganic filler 14 is not particularly limited, but is preferably 20 W/(m/K) or more, and more preferably 30 W/(m/K) or more at a measurement temperature of 300 K.

The content of the inorganic filler 14 in the first conductive paste 6 is not particularly limited, but is preferably in a range of 4 mass % to 50 mass % when the total amount of the eutectic powder 11, the active metal powder 12, and the inorganic filler 14 is 100 mass %.

### Other Components

The other components in the first conductive paste 6 are not particularly limited, and examples thereof include a reducing agent such as organic acid and other eutectic alloy powders other than the eutectic powder 11 of silver and copper. One type of material among these materials can be used alone, or two or more types of materials can be used in combination.

Examples of the other eutectic alloy powders other than the eutectic powder 11 of silver and copper include powders of eutectic alloy of copper and zinc and eutectic alloy of copper and tin. One type of material among these materials can be used alone, or two or more types of materials can be used in combination.

The melting points of the other eutectic alloy powders are not particularly limited, but are preferably in a range of 700° C. to 1200° C., more preferably in a range of 720° C. to 1100° C., and even more preferably in a range of 780° C. to 850° C. The melting point of the eutectic alloy powder is lowered, so that the thermal load applied to the material of the ceramic plate 1 or the like can be reduced, and discoloration can be reduced.

The contents of the other eutectic alloy powders are not particularly limited as long as the effect of the present disclosure is not impaired.

### (S5) Sintering

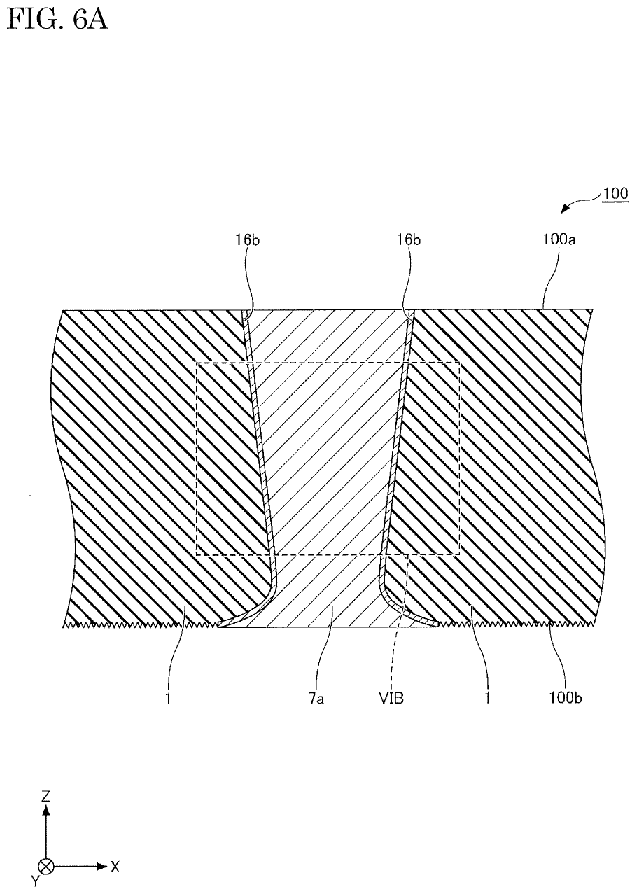

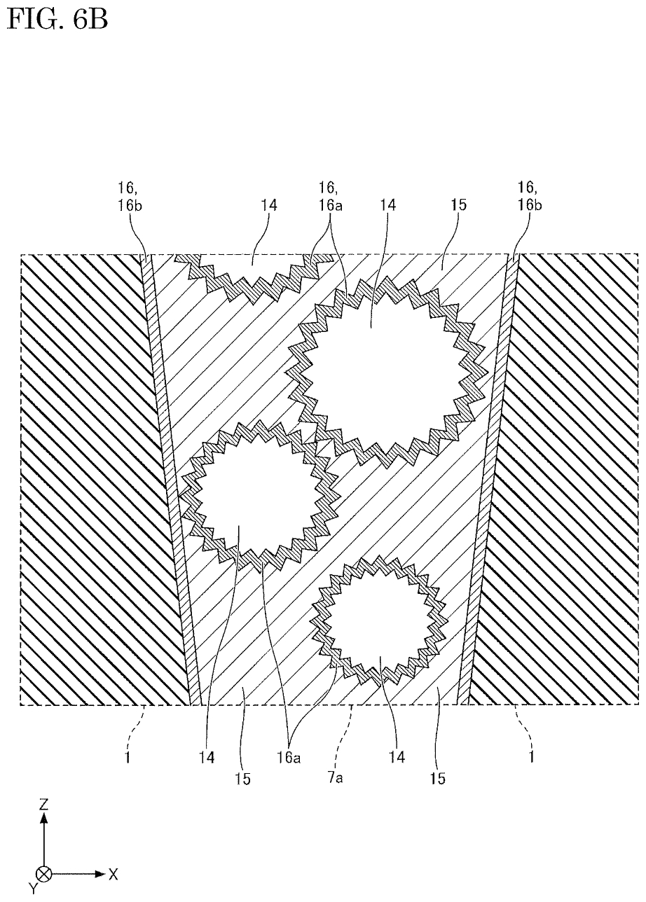

FIG. 6A is a schematic cross-sectional view illustrating an example of sintering in the method for manufacturing a ceramic substrate according to the first embodiment. FIG. 6B is an enlarged cross-sectional view schematically illustrating a state of a conductive member by enlarging a region VIB in FIG. 6A.

In S5 of sintering, the first conductive paste 6 is sintered. S5 of sintering is performed, so that the ceramic substrate 100 can be obtained, which has a first surface 100a and a second surface 100b on the side opposite to the first surface 100a, and includes the through hole 2 that connects the first surface 100a and the second surface 100b, and has the first conductive member 7a disposed in the through hole 2.

To be specific, in S5 of sintering, the first conductive paste 6 having filled the through hole 2 of the ceramic plate 1 in S4 of disposing a first conductive paste is sintered, thereby forming the first conductive member 7a. Even when the first conductive paste 6 is disposed covering at least part of the first surface 1a and the second surface 1b of the ceramic plate 1 in S4 of disposing a first conductive paste, the first conductive paste 6 is similarly sintered to form the first conductive member 7a.

In S5 of sintering, the first conductive paste 6 is preferably dried after S4 of disposing a first conductive paste and before the first conductive paste 6 is sintered. The drying temperature is not particularly limited, and examples thereof include a temperature lower than the sintering temperature of the first conductive paste 6.

The sintering atmosphere when the first conductive paste 6 is sintered is not particularly limited, but is preferably an Ar atmosphere of 99.9% or more or a vacuum atmosphere of 10-5 Pa or less.

The sintering temperature when sintering the first conductive paste 6 can be a temperature at which at least a part of the first conductive paste 6 melts. In particular, the sintering is preferably performed at a temperature equal to or lower than the melting point of the inorganic filler 14, at which the eutectic powder 11 contained in the first conductive paste 6 melts. The sintering temperature when the first conductive paste 6 is sintered is preferably in a range of 700° C. to 1200° C., more preferably in a range of 720° C. to 1000° C., and even more preferably in a range of 750° C. to 900° C.

The sintering time when the first conductive paste 6 is sintered is not particularly limited, but is preferably in a range of 5 minutes to 90 minutes, more preferably in a range of 10 minutes to 60 minutes, and even more preferably in a range of 15 minutes to 30 minutes.

The first conductive member 7a produced using the first conductive paste 6 includes, for example, a metal 15, the metal compound 16, and the inorganic filler 14. The solvent 13 is evaporated and removed by sintering of the first conductive paste 6.

In the first conductive member 7a, for example, when the total content of the metal 15, the metal compound 16, and the inorganic filler 14 is 100 mass %, the content of the metal 15 is preferably in a range of 40 mass % to 95 mass %, the content of the metal compound 16 is preferably in a range of 1 mass % to 10 mass %, and the content of the inorganic filler 14 is preferably in a range of 5 mass % to 50 mass %. When the first conductive member 7a includes the inorganic filler 14 at a predetermined ratio, the volume shrinkage can be reduced. In addition, when the first conductive member 7a includes the metal 15 at a predetermined ratio, the inorganic filler 14 can be dispersed into the metal 15 continuous with the inorganic filler 14.

The metal 15 is a metal member serving as a core of the first conductive member 7a together with the inorganic filler 14 in the first conductive member 7a. In the metal 15, the inorganic filler 14 is arranged in a dispersed state.

In S5 of sintering, the eutectic powder 11 in the first conductive paste 6 is sintered to become the metal 15. Accordingly, the type of metal of the eutectic powder 11 can be specified from the type of metal of the metal 15, and examples thereof include silver, copper, a eutectic alloy of silver and copper, a eutectic alloy of copper and zinc, and a eutectic alloy of copper and tin. Among these, silver and copper having high thermal conductivity and high electrical conductivity are preferable for the metal 15.

The inorganic filler 14 is arranged in the first conductive member 7a in a state in which a plurality of particles thereof are dispersed. The expression “a plurality of inorganic fillers 14” indicates that the inorganic filler 14 is not one particle, but includes a plurality of particles.

An area of the inorganic filler 14 is preferably in a range of 10 μm² to 75 μm² per 100 μm² in a cross-sectional view of the first conductive member 7a in the thickness direction of the ceramic substrate 100.

The metal compound 16 is formed by sintering the active metal powder 12. By sintering the first conductive paste 6, a reaction layer of the inorganic filler 14 and the active metal powder 12 is formed on the surface of the inorganic filler 14. The metal compound 16 is mainly disposed on at least a part or the whole of the surface of the inorganic filler 14, and on at least a part of the inner wall of the through hole 2 in the ceramic plate 1. The metal compound 16 includes a filler-surface metal compound 16a disposed on the surface of the inorganic filler 14, and the nitride coating film 16b disposed on at least a part of the inner wall of the through hole 2 in the ceramic plate 1. Preferably, the active metal powder 12, the inorganic filler 14, and components of the inner wall of the through hole 2 in the ceramic plate 1 are sintered, whereby the filler-surface metal compound 16a and the nitride coating film 16b are disposed as reaction products.

The filler-surface metal compound 16a is the metal compound 16 and disposed covering at least a part or the whole of the surface of the inorganic filler 14. When the inorganic filler 14 is AlN or Si₃N₄, for example, the filler-surface metal compound 16a is formed on the surface of the inorganic filler 14 as TiN by a reaction between the inorganic filler 14 and TiH₂ in the active metal powder 12 before sintering, for example. Jagged irregularities are continuously formed on the surface of the filler-surface metal compound 16a, and the inorganic filler 14 is also in a state in which jagged irregularities are formed on its surface. The inorganic filler 14 having the filler-surface metal compound 16a disposed on its surface is in a state of being dispersed in the first conductive member 7a continuous with the inorganic filler 14.

The nitride coating film 16b is disposed, as the metal compound 16, on at least a part of the inner wall of the through hole 2 in the ceramic plate 1. In a case in which the ceramic plate 1 is made of at least one selected from the group consisting of silicon nitride, aluminum nitride, and boron nitride, for example, and when the active metal powder 12 before sintering contains, for example, TiH₂, a reaction product TiN is generated and the nitride coating film 16b is formed as a compound on the inner wall of the through hole 2 in the ceramic plate 1. The nitride coating film 16b is in a state of continuously forming jagged irregularities on the inner wall of the through hole 2 in the ceramic plate 1, so that the connection strength between the inner wall of the through hole 2 in the ceramic plate 1 and the first conductive member 7a is improved.

In the method for manufacturing a ceramic substrate according to the first embodiment, the damaged layer 5 is removed in S2 of bringing into contact, which allows for reducing the occurrence of cracking in the second surface 100b of the ceramic substrate 100. In addition, by S3 of blasting, the through hole 2 becomes, in the vicinity of the second opening 4 in the second surface 1b of the ceramic plate 1, a tapered shape in which the opening diameter decreases from the second surface 1b gradually in the thickness direction of the ceramic plate 1 in a cross-sectional view, allowing for facilitating dissipation of the stress exerted on the ceramic substrate 100, and it is possible to further reduce the occurrence of cracking in the second surface 100b of the ceramic substrate 100. Reducing the occurrence of cracking can improve the adhesion between the first conductive member 7a and the ceramic plate 1, and can improve the reliability of conduction.

### Second Embodiment

A method for manufacturing a ceramic substrate according to a second embodiment is different from the method for manufacturing a ceramic substrate according to the first embodiment in that an etchant contains an acid solution as a pH adjusting agent in S2 of bringing into contact. In this case, the etchant does not contain an alkaline solution.

Examples of the etchant containing an acid solution include an etchant containing, as a pH adjusting agent, one or more types selected from the group consisting of hydrochloric acid, sulfuric acid, phosphoric acid, citric acid, and acetic acid.

The concentration of the pH adjusting agent contained in the acid solution-containing etchant is not particularly limited as long as the damaged layer 5 can be removed, and can be appropriately selected in accordance with the purpose, but is preferably 8.0 mol/L or more, and more preferably 10.0 mol/L or more. When the concentration of the pH adjusting agent contained in the acid solution-containing etchant is 8.0 mol/L or more, the inner surface defining the through hole 2 of the ceramic plate 1 can be efficiently etched, and the damaged layer 5 can be removed.

In S2 of bringing into contact, the temperature at which the etchant containing the acid solution and the inner surface defining the through hole 2 of the ceramic plate 1 are brought into contact with each other is not particularly limited as long as the damaged layer 5 can be removed, and can be appropriately selected in accordance with the purpose, but is preferably lower than 100° C., and more preferably in a range of 20° C. to 80° C. When the temperature at which the etchant containing the acid solution and the inner surface defining the through hole 2 of the ceramic plate 1 are brought into contact with each other is lower than 100° C., it is possible to prevent the etchant containing the acid solution from boiling. When the temperature at which the etchant containing the acid solution and the inner surface defining the through hole 2 of the ceramic plate 1 are brought into contact with each other is 20° C. or higher, the inner surface defining the through hole 2 of the ceramic plate 1 can be efficiently etched.

In S2 of bringing into contact, the period of time during which the etchant containing the acid solution and the inner surface defining the through hole 2 of the ceramic plate 1 are brought into contact with each other is not particularly limited as long as the damaged layer 5 can be removed, and can be appropriately selected in accordance with the purpose, but is preferably in a range of 5 minutes to 90 minutes, and more preferably in a range of 10 minutes to 60 minutes. When the period of time during which the etchant containing the acid solution and the inner surface defining the through hole 2 of the ceramic plate 1 are brought into contact with each other is 5 minutes or longer, the inner surface defining the through hole 2 of the ceramic plate 1 can be efficiently etched. When the period of time during which the etchant containing the acid solution and the inner surface defining the through hole 2 of the ceramic plate 1 are brought into contact with each other is 60 minutes or shorter, the opening diameter and the shape of the through hole 2 are easily adjusted to the desired ones, and it is possible to prevent the thickness of the ceramic plate 1 from being reduced by etching.

### Third Embodiment

A method for manufacturing a ceramic substrate according to a third embodiment is different from the method for manufacturing a ceramic substrate according to the first embodiment in that the first conductive paste 6 used in S4 of disposing a first conductive paste further contains at least one type of powder 17 selected from the group consisting of a copper powder, a silver powder, a powder of an alloy of silver and copper, and a ceramic powder.

S4 of disposing a first conductive paste in the method for manufacturing a ceramic substrate according to the third embodiment can also be applied to S4 of disposing a first conductive paste in the method for manufacturing a ceramic substrate according to the second embodiment.

The content of the at least one type of powder 17 selected from the group consisting of the copper powder, the silver powder, the powder of the alloy of silver and copper, and the ceramic powder in the first conductive paste 6 is not particularly limited as long as the effect of the present disclosure is not impaired, but is preferably in a range of 5 mass % to 20 mass % when the total amount of the eutectic powder 11, the active metal powder 12, the inorganic filler 14, and the powder 17 is 100 mass %.

The copper powder, the silver powder, and the powder of the alloy of silver and copper are more excellent in conductivity than the eutectic powder 11 of silver and copper. Since the copper powder has a melting point of 1084° C. and the silver powder has a melting point of 962° C., the copper powder and the silver powder are less likely to be melted in the first conductive paste 6 at the time of sintering in S5 of sintering, and can be present in a state of being dispersed as powder in the first conductive member 7a. This can further improve the conductivity of the ceramic substrate 100.

In addition, since the ceramic powder also has a high melting point, the ceramic powder is less likely to be melted in the first conductive paste 6 at the time of sintering in S5 of sintering, and can be present in a state of being dispersed as powder in the first conductive member 7a. This can reduce a difference in linear expansion coefficient between the ceramic plate 1 and the first conductive member 7a, and further improve the reliability of the ceramic substrate 100.

### Fourth Embodiment

A method for manufacturing a ceramic substrate according to a fourth embodiment is different from the method for manufacturing a ceramic substrate according to the first embodiment in that blasting is performed on the through hole 2 from the first surface 1a in S3 of blasting.

S3 of blasting in the method for manufacturing a ceramic substrate according to the fourth embodiment can also be applied to S3 of blasting in the method for manufacturing a ceramic substrate according to the second embodiment as well as S3 of blasting in the method for manufacturing a ceramic substrate according to the third embodiment.

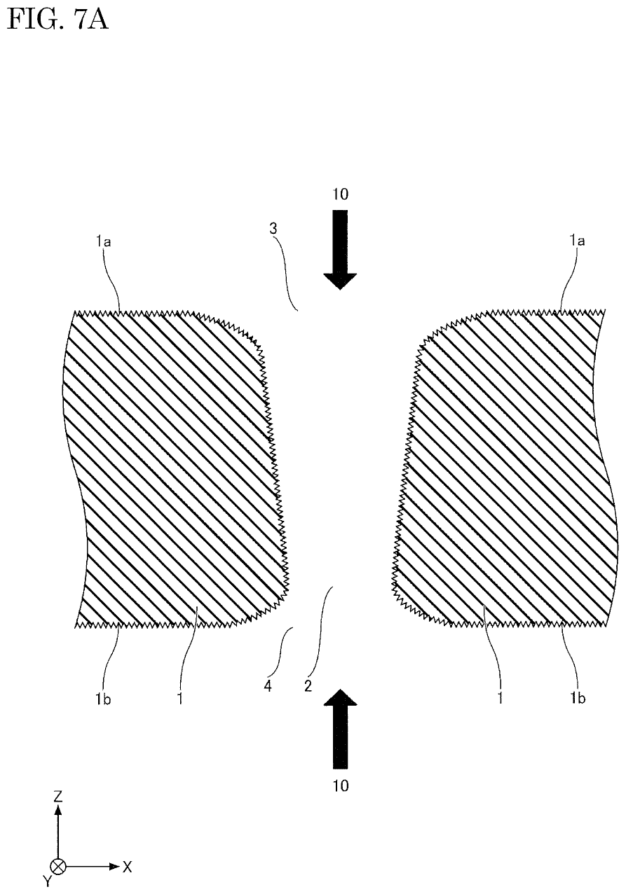

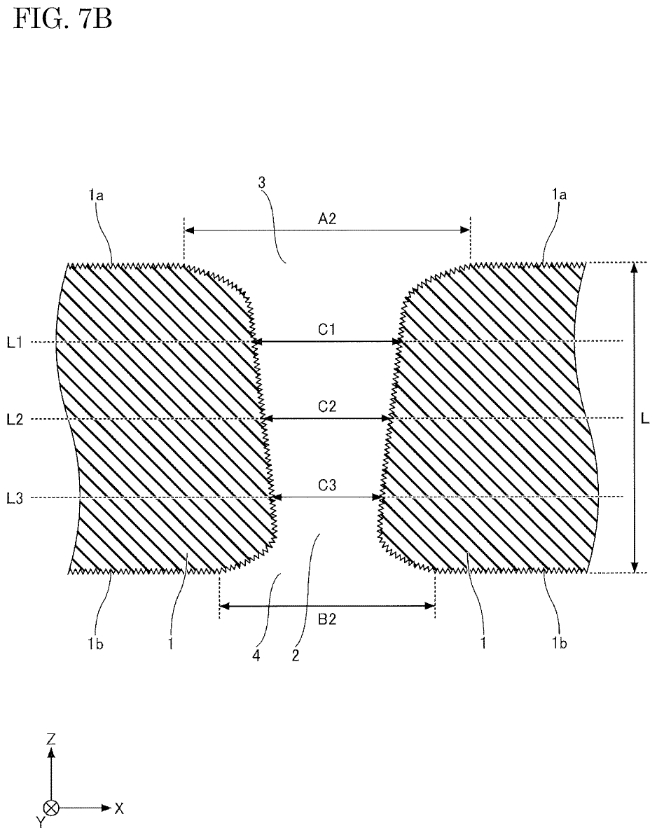

FIG. 7A is a schematic cross-sectional view illustrating an example of blasting in the method for manufacturing a ceramic substrate according to the fourth embodiment. FIG. 7B is a schematic cross-sectional view illustrating the size of each part in FIG. 7A.

In the method for manufacturing a ceramic substrate according to the fourth embodiment, in S3 of blasting, an abrasive 10 is supplied from the second surface 1b and the first surface 1a, and blasting is performed on the second surface 1b, the first surface 1a, and the through hole 2. With this blasting, the ceramic plate 1 defining the second opening 4 is shaved at the second opening 4 of the through hole 2 formed in the second surface 1b, and the ceramic plate 1 defining the first opening 3 of the through hole 2 formed in the first surface 1a is also shaved. In addition, the surfaces of the second surface 1b and first surface 1a and the surface of the inner surface of the through hole 2 become roughened.

In the method for manufacturing a ceramic substrate according to the fourth embodiment as well, C1>C2>C3 is satisfied, A2>B2 is satisfied, A2>C1 is satisfied, and B2>C3 is satisfied, where a maximum diameter of the first opening 3 of the through hole 2 is defined as A2, the first opening 3 being formed in the first surface 1a, a maximum diameter of the second opening 4 of the through hole 2 is defined as B2, the second opening 4 being formed in the second surface 1b, and an average length between the first surface 1a and the second surface 1b is defined as L, and where a maximum diameter of the through hole 2 in a cross section in a direction substantially orthogonal to the thickness direction of the ceramic plate 1 at a location of L/4 from the first surface 1a, that is, at a location L1, is defined as C1, a maximum diameter of the through hole 2 in a cross section in the direction substantially orthogonal to the thickness direction of the ceramic plate 1 at a location of L/2 from the first surface 1a, that is, at a location L2, is defined as C2, and a maximum diameter of the through hole 2 in a cross section in the direction substantially orthogonal to the thickness direction of the ceramic plate 1 at a location of 3L/4 from the first surface 1a, that is, at a location L3, is defined as C3.

Preferably, the through hole 2 has, in the vicinity of the first opening 3 in the first surface 1a, a tapered shape in which the opening diameter decreases from the first surface 1a gradually in the thickness direction of the ceramic plate 1 in a cross-sectional view.

The method for manufacturing a ceramic substrate according to the fourth embodiment allows for reducing the occurrence of cracking in both the first surface 100a and second surface 100b of the ceramic substrate 100. In addition, in S3 of blasting, the through hole 2 becomes, in the vicinity of the first opening 3 in the first surface 1a of the ceramic plate 1, and in the vicinity of the second opening 4 in the second surface 1b of the ceramic plate 1, a tapered shape in which the opening diameter decreases from each of the first surface 1a and the second surface 1b gradually in the thickness direction of the ceramic plate 1 in a cross-sectional view, allowing for facilitating dissipation of the stress on the ceramic substrate 100, so that the occurrence of cracking can be further reduced in the first surface 100a and second surface 100b of the ceramic substrate 100.

### Fifth Embodiment

A method for manufacturing a ceramic substrate according to a fifth embodiment is different from the method for manufacturing a ceramic substrate according to the first embodiment in that S1 of preparing a ceramic plate 1 in the method for manufacturing a ceramic substrate according to the first embodiment or the second embodiment is changed to S21 of preparing the ceramic plate 1 not including a through hole 2, instead of a commercially available ceramic plate 1, and processing the ceramic plate 1 to form the through hole 2 in such a manner that a maximum diameter B1 of a second opening 4 of the through hole formed in a second surface 1b is less than 0.90 times a maximum diameter A1 of a first opening 3 of the through hole 2 formed in the first surface 1a as described below. Hereinafter, a change to S22 of bringing into contact accompanying the change to S21 of preparing will also be described.

S1 of preparing in the method for manufacturing a ceramic substrate according to the third embodiment as well as the fourth embodiment can be changed to S21 of preparing in the method for manufacturing a ceramic substrate according to the fifth embodiment.

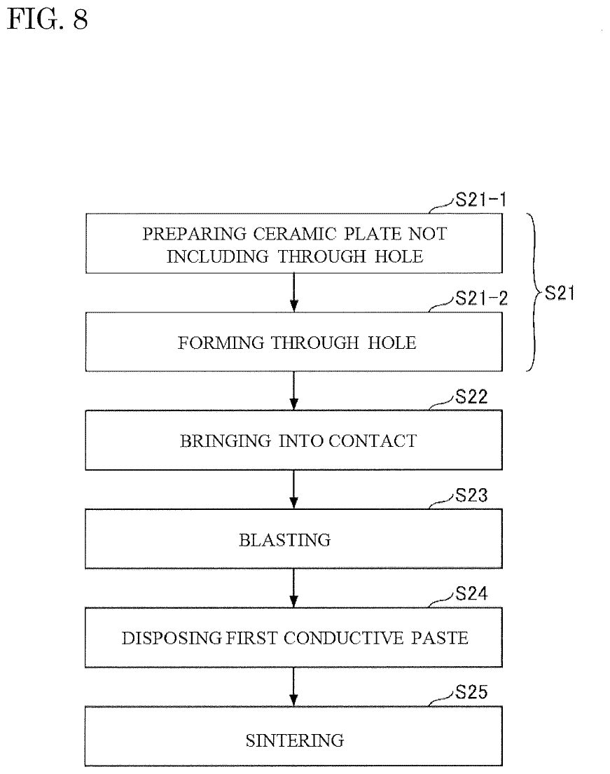

FIG. 8 is a flowchart illustrating an example of preparing a ceramic plate in the method for manufacturing a ceramic substrate according to the fifth embodiment.

### S21 Preparing

### S21-1 Preparing Ceramic Plate Not Including Through Hole

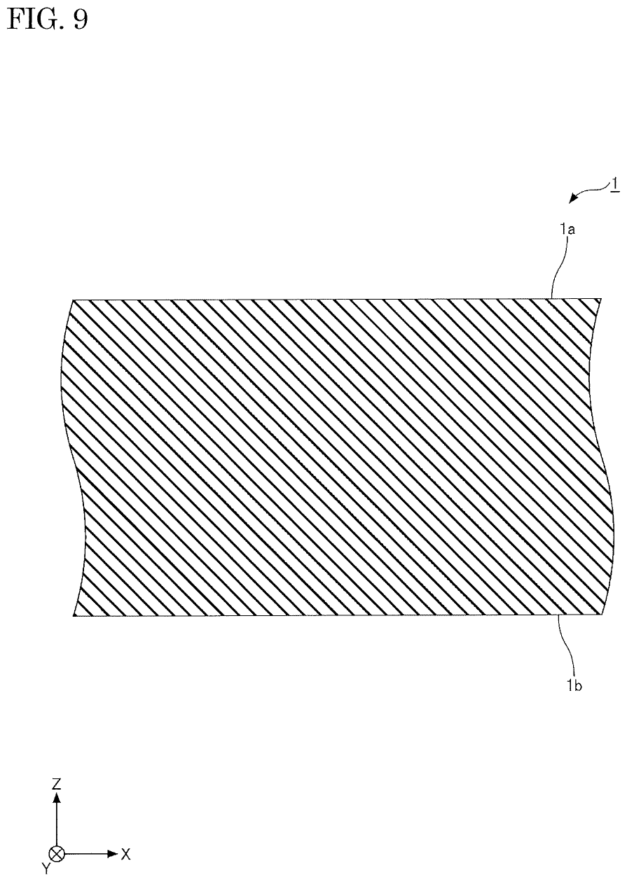

FIG. 9 is a schematic cross-sectional view illustrating an example of preparing a ceramic plate not including a through hole in the method for manufacturing a ceramic substrate according to the fifth embodiment.

In S21 of preparing a ceramic plate, the ceramic plate 1 including the first surface 1a and the second surface 1b on the side opposite to the first surface 1a is prepared. The ceramic plate 1 in S21 of preparing a ceramic plate is the same as or similar to the ceramic plate 1 in the method for manufacturing a ceramic substrate according to the first embodiment or the second embodiment, except that the ceramic plate 1 does not include the through hole 2.

### S21-2 Forming Through Hole

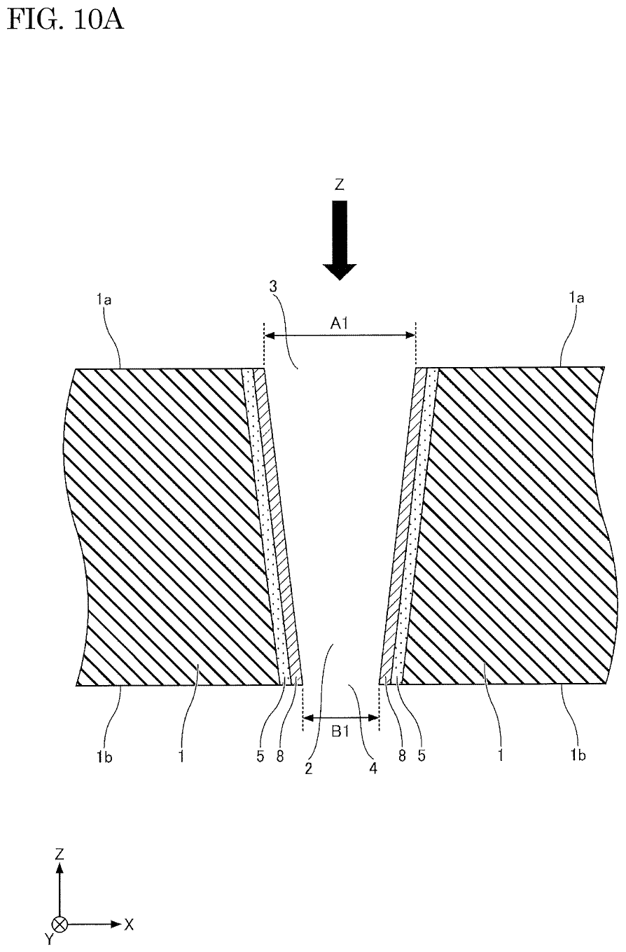

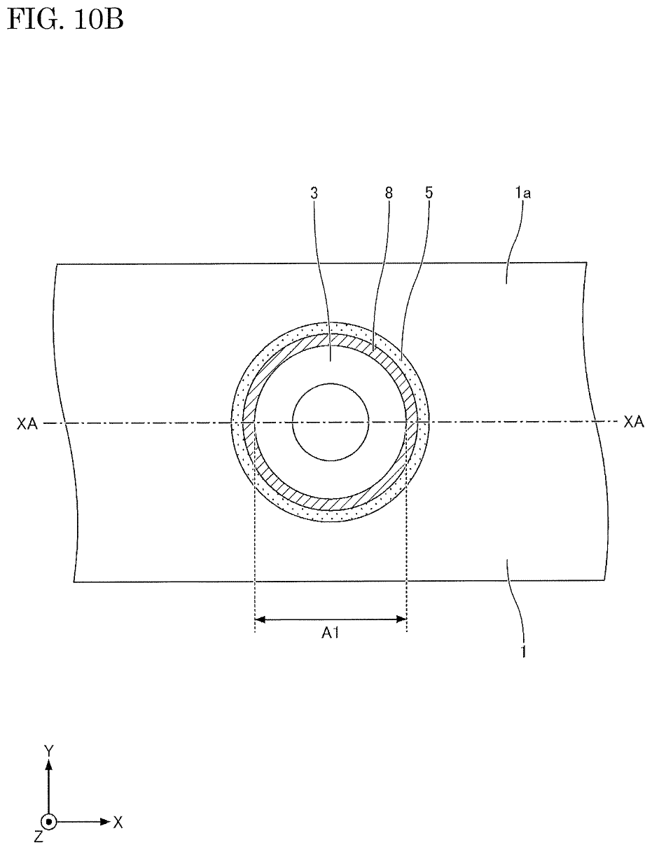

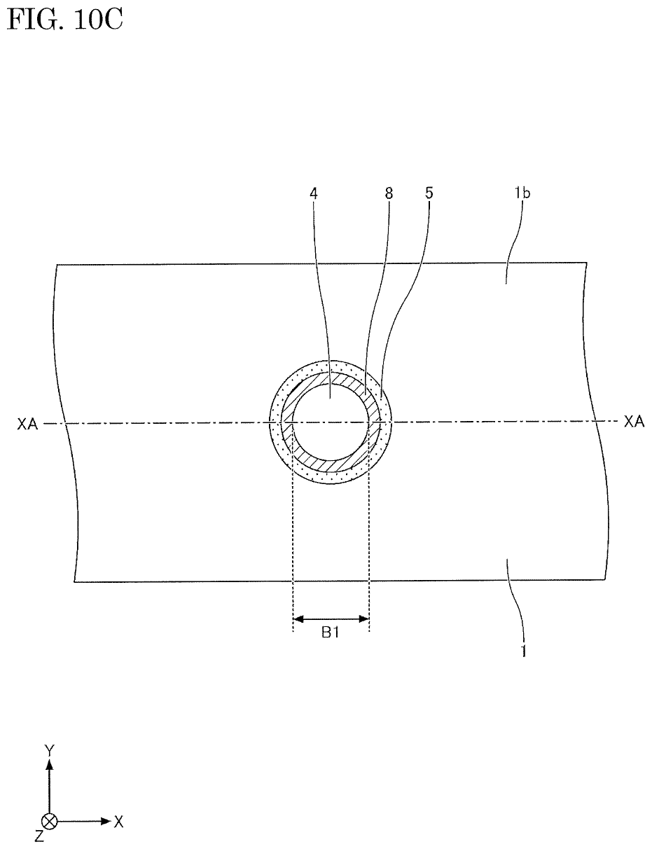

FIG. 10A is a schematic cross-sectional view illustrating an example of forming a through hole in the method for manufacturing a ceramic substrate according to the fifth embodiment. FIG. 10B is a schematic top view of a ceramic plate in FIG. 10A. FIG. 10C is a schematic bottom view of the ceramic plate in FIG. 10A. FIG. 10A is a schematic cross-sectional view taken along a line XA-XA in FIGS. 10B and 10C.

In S21-2 of forming a through hole, the through hole 2 is formed in the ceramic plate 1 in such a manner that the maximum diameter B1 of the second opening 4 of the through hole formed in the second surface 1b is less than 0.90 times the maximum diameter A1 of the first opening 3 of the through hole 2 formed in the first surface 1a. In the ceramic plate 1, the lower limit for the maximum diameter B1 of the second opening 4 of the through hole formed in the second surface 1b relative to the maximum diameter A1 of the first opening 3 of the through hole 2 formed in the first surface 1a is not particularly limited, but the maximum diameter B1 is preferably 0.5 times or more, and is more preferably 0.6 times or more the maximum diameter A1. Thus, the maximum diameter of the second opening 4 can be reduced. An angle formed between the inner surface defining the through hole 2 and the second surface 1b in a cross-sectional view can be 45 degrees or more, preferably 60 degrees or more, and more preferably 75 degrees or more. Thus, the occurrence of cracking at the time of forming the through hole 2 can be reduced.

In S21-2 of forming a through hole, examples of a method for forming the through hole 2 in a predetermined shape in the ceramic plate 1 include a method of irradiation with laser light Z and a method of drilling. One type of method among these methods can be used alone, or two or more types of methods can be used in combination. Among these, the method of irradiation with the laser light Z is preferable in that the through hole 2 having a small size can be easily formed even when the sintered ceramic plate 1 is used.

In the case of using the method of irradiation with the laser light Z in S21-2 of forming a through hole, the ceramic plate 1 is irradiated with the laser light Z from the first surface 1a toward the second surface 1b to form the through hole 2 in the ceramic plate 1. Specifically, by irradiating a predetermined region of the first surface 1a of the ceramic plate 1 with the laser light Z in the Z-axis direction to thermally process the predetermined region, the ceramic on the first surface 1a of the ceramic plate 1 are removed due to melting and sublimation mainly in the irradiated part having absorbed the laser light Z. As a result, the through hole 2 is formed continuous from the first surface 1a to the second surface 1b.

The through hole 2 can be formed by one-time irradiation with the laser light Z, or can be formed by gradually removing the ceramic by emitting the laser light Z a plurality of times.

However, the same part is preferably irradiated only once with the laser light Z.

The laser light Z is not particularly limited as long as the laser light Z can form the through hole 2 such that the maximum diameter B1 of the second opening 4 of the through hole formed in the second surface 1b is less than 0.90 times the maximum diameter A1 of the first opening 3 of the through hole 2 formed in the first surface 1a of the ceramic plate 1. However, the laser light Z that can be used to perform thermal processing is preferable, and laser light having an oscillation wavelength equal to or greater than 750 nm or laser light having an output equal to or higher than 200 W is more preferable.

The pulse width of the laser light Z is not particularly limited, but the laser light Z preferably includes a continuous wave (CW). The continuous wave is a wave in which the pulse width of the laser light Z is maximized in a repetition interval of the pulse.

Specific examples of the laser light Z include Nd:YAG laser light, Nd:YVO₄ laser light, CO₂ laser light, and fiber laser light and disk laser light with high power regardless of the wavelength. One type of laser light among these types of laser light can be used alone, or two or more types of laser light can be used in combination. Among these, fiber laser light is preferable as the laser light Z.

The atmosphere conditions under which the laser light Z is emitted are not particularly limited, and examples thereof include a vacuum atmosphere and an inert gas atmosphere. Examples of the inert gas include N₂ and CO₂. One type of inert gas among these types of inert gases can be used alone, or two or more types of inert gases can be used in combination.

The pulse width, power, and wavelength of the laser light Z are not particularly limited, and processing can be performed, for example, under conditions of fiber laser light (wavelength: 1070 nm, power: 1000 W, frequency: 100 Hz, irradiation time: 1.5 milliseconds) or the like. However, the conditions are not limited to these as long as the through hole 2 can be formed in such a manner that the maximum diameter B1 of the second opening 4 of the through hole 2 formed in the second surface 1b is less than 0.90 times the maximum diameter A1 of the first opening 3 of the through hole 2 formed in the first surface 1a.

When the ceramic plate 1 is irradiated with the laser light Z, irregularities are formed in the vicinity of the irradiated part of the ceramic plate 1, that is, on the inner surface defining the through hole 2, whereby the inner surface is roughened. Recessed portions of the inner surface defining the through hole 2 are an irregular minute structure. In the present disclosure, the irregular minute structure with the recessed portions of the inner surface defining the through hole 2 can be referred to as, for example, a root shape or a tree shape.

In the case of using the ceramic plate 1 containing aluminum nitride as a main material, an aluminum layer 8 can be deposited continuously or fragmentarily on a part of the ceramic plate 1 irradiated with the laser light Z, that is, on the inner surface defining the through hole 2. The aluminum layer 8 is formed in a state of entering the irregularities of the inner surface defining the through hole 2. This is because, when the aluminum layer 8 is formed, a rapid temperature rise occurs in the aluminum nitride due to the irradiation with the laser light Z, and a phase change occurs in which part of the aluminum nitride melts and sublimates, thereby causing ablation. In other words, a material making up the ceramic plate 1 is present in recessed portions having a root shape on the lower surface of the aluminum layer 8. As described above, the lower surface of the aluminum layer 8 on the side on which the ceramic plate 1 is disposed contains the material making up the ceramic plate 1 and the deposited aluminum.

In the ceramic plate 1 irradiated with the laser light Z, heat generated by the irradiation with the laser light Z spreads not only to the part irradiated with the laser light Z, but also to a peripheral part from the part irradiated with the laser light Z. Thus, the deposition of the aluminum layer 8 from the ceramic plate 1 occurs not only in the part irradiated with the laser light Z, but also in the peripheral part inside the ceramic plate 1 in the Z-axis direction from the irradiated part. At this time, the heat generated by the irradiation with the laser light Z and spreading to the peripheral part causes the deterioration of the ceramic plate 1, and consequently the damaged layer 5 is also formed. Thus, the damaged layer 5 is formed between the aluminum layer 8 and the ceramic plate 1.

S22 Bringing into Contact

In S22 of bringing into contact in the method for manufacturing a ceramic substrate according to the fifth embodiment, the inner surface defining the through hole 2 of the ceramic plate 1 and an etchant are brought into contact with each other. At this time, the aluminum layer 8 disposed on the inner surface of the through hole 2 and the etchant come into contact with each other, and the damaged layer 5 and the etchant also come into contact with each other. As a result of this, the aluminum layer 8 and the damaged layer 5 are removed in the same manner as or a similar manner to the method for manufacturing a ceramic substrate according to the first embodiment or the second embodiment.

### Form of Using Etchant Containing Alkaline Solution

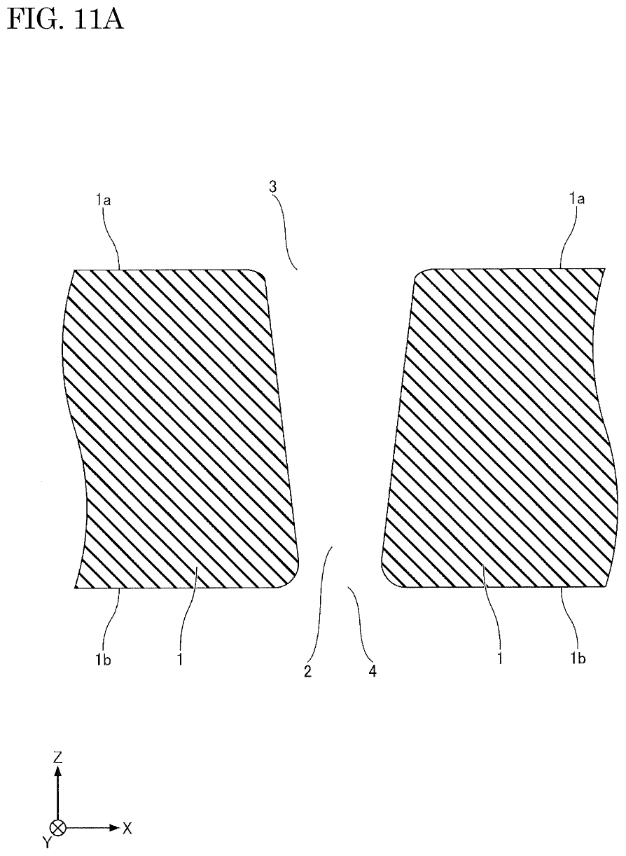

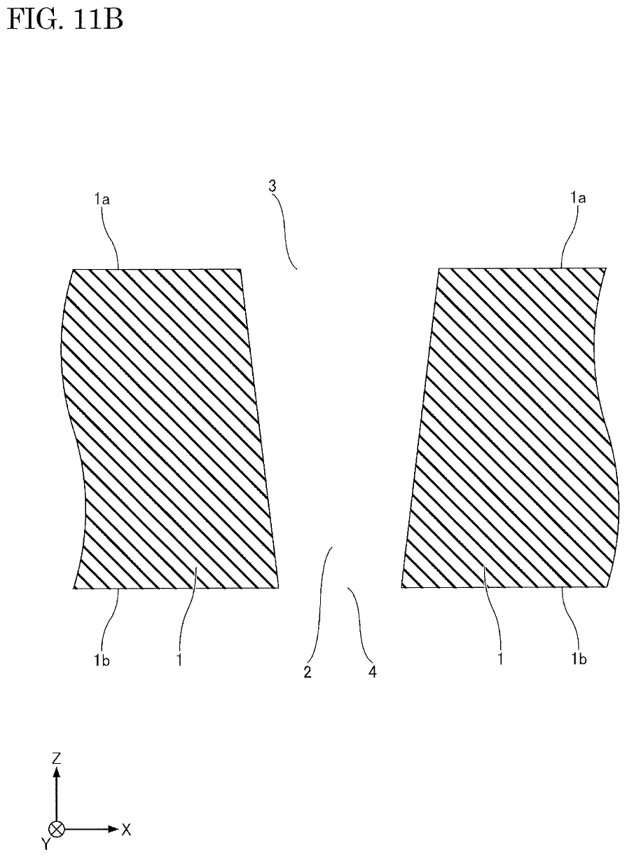

FIG. 11A is a schematic cross-sectional view illustrating an example of a case of using an etchant containing an alkaline solution in bringing into contact in the method for manufacturing a ceramic substrate according to the fifth embodiment.

Here, in a case of using an etchant containing an alkaline solution as the etchant, it is preferable to use an etchant having a higher etching reaction rate for aluminum nitride than for aluminum. Examples of the alkaline solution contained in such an etchant include the alkaline solution exemplified in the method for manufacturing a ceramic substrate according to the first embodiment.

When an etchant containing an alkaline solution having a higher etching reaction rate for aluminum nitride than for aluminum is brought into contact with the laser-processed ceramic plate 1, the aluminum layer 8 inside the through hole 2 is less easily etched, and aluminum nitride as the main material of the ceramic plate is easily etched. Thus, a portion of the damaged layer 5 around the first opening 3 and a portion of the damaged layer 5 around the second opening 4 of the through hole 2 are most easily etched, and the ceramic plate 1 is gradually etched from the first opening 3 and the second opening 4. Accordingly, the aluminum layer 8 is also removed from the first opening 3 side and the second opening 4 side along with the etching of the aluminum nitride of the ceramic plate 1. On the other hand, the inner surface of the through hole 2 is less easily etched because the ceramic plate 1 is covered with the aluminum layer 8. As a result, in the etching reaction process, the ceramic plate 1 defining the first opening 3 of the through hole 2 is shaved, and a tapered shape in which the opening diameter decreases from the first surface 1a gradually in the thickness direction of the ceramic plate 1 is formed before performing S23 of blasting. Likewise, in the etching reaction process, the ceramic plate 1 defining the second opening 4 of the through hole 2 is shaved, and a tapered shape in which the opening diameter decreases from the second surface 1b gradually in the thickness direction of the ceramic plate 1 is formed before performing S23 of blasting.

Therefore, when an alkaline solution-containing etchant is used as the etchant for the laser-processed ceramic plate 1, the ceramic plate 1 can be more efficiently formed into a shape satisfying C1>C2>C3, A2>B2, A2>C1, and B2>C3 in S23 of blasting, as compared with the method for manufacturing a ceramic substrate according to the first embodiment.

### Form of Using Etchant Containing Acid Solution

FIG. 11B is a schematic cross-sectional view illustrating an example of a case of using an etchant containing an acid solution in bringing into contact in the method for manufacturing a ceramic substrate according to the fifth embodiment.

Here, in a case of using an etchant containing an acid solution as the etchant, it is preferable to use an etchant having a higher etching reaction rate for aluminum than for aluminum nitride. Examples of the acid solution contained in such an etchant include the acid solution exemplified in the method for manufacturing a ceramic substrate according to the second embodiment.

When an etchant containing an acid solution having a higher etching reaction rate for aluminum than for aluminum nitride is brought into contact with the laser-processed ceramic plate 1, the aluminum layer 8 inside the through hole 2 is easily etched, and aluminum nitride as the main material of the ceramic plate is less easily to be etched. Because of this, the aluminum layer 8 on the inner surface of the through hole 2 and the etchant containing the acid solution uniformly react with each other, and the aluminum layer 8 is removed and the damaged layer 5 is also removed.

By irradiating the ceramic plate 1 with the laser light Z, burrs of the aluminum layer 8 can be generated on the first surface 1a of the ceramic plate 1 defining the first opening 3 and on the second surface 1b of the ceramic plate 1 defining the second opening 4. When the burrs and the etchant containing the acid solution are brought into contact with each other, the ceramic plate 1 defining the first opening 3, and the ceramic plate 1 defining the second opening 4 are likely to be removed. Then, in the etching reaction process, the ceramic plate 1 defining the first opening 3 of the through hole 2 is shaved, and a tapered shape in which the opening diameter decreases from the first surface 1a gradually in the thickness direction of the ceramic plate 1 can be formed before performing S23 of blasting. Likewise, in the etching reaction process, the ceramic plate 1 defining the second opening 4 of the through hole 2 is shaved, and a tapered shape in which the opening diameter decreases from the second surface 1b gradually in the thickness direction of the ceramic plate 1 can be formed before performing S23 of blasting. However, a curved line R of the tapered shape is gentler than that in the case of using the etchant containing the alkaline solution.

Since the method for manufacturing a ceramic substrate according to the fifth embodiment includes the processing of the through hole 2 in the ceramic plate 1, the degree of freedom in designing the ceramic substrate can be further enhanced as compared with the method for manufacturing a ceramic substrate according to the first embodiment or the second embodiment. In particular, when the laser light Z is used for processing the through hole 2, the through hole 2 can be easily made small in diameter, the through hole 2 can be accurately formed at a desired position, and the size of the through hole 2 can be adjusted to a desired fixed size.

### Sixth Embodiment

A method for manufacturing a ceramic substrate according to a sixth embodiment is different from the method for manufacturing a ceramic substrate according to the first embodiment in that, the method according to the sixth embodiment further includes, after the first conductive paste 6 is disposed and before sintering is performed in the method for manufacturing a ceramic substrate according to the first embodiment, S35 of disposing a first covering member 18a on the first surface 1a, disposing a second covering member 18b on the second surface 1b, and disposing a second conductive paste 19 on the surface of the first conductive paste 6.

In the method for manufacturing a ceramic substrate according to the sixth embodiment, the first conductive paste 6 and the second conductive paste 19 can be sintered separately or can be sintered simultaneously, but it is efficient and preferable to sinter the first conductive paste 6 and the second conductive paste 19 simultaneously in S36 of sintering.

S35 of disposing a second conductive paste in the method for manufacturing a ceramic substrate according to the sixth embodiment can be S35 of disposing a second conductive paste to be further included in the method for manufacturing a ceramic substrate according to the second embodiment, the third embodiment, the fourth embodiment, and the fifth embodiment.

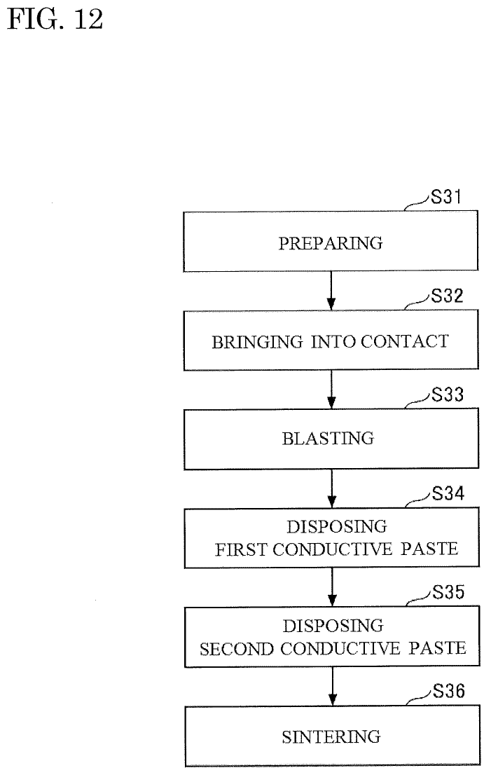

FIG. 12 is a flowchart illustrating an example of preparing a ceramic plate in the method for manufacturing a ceramic substrate according to the sixth embodiment.

### S35 Disposing Second Conductive Paste

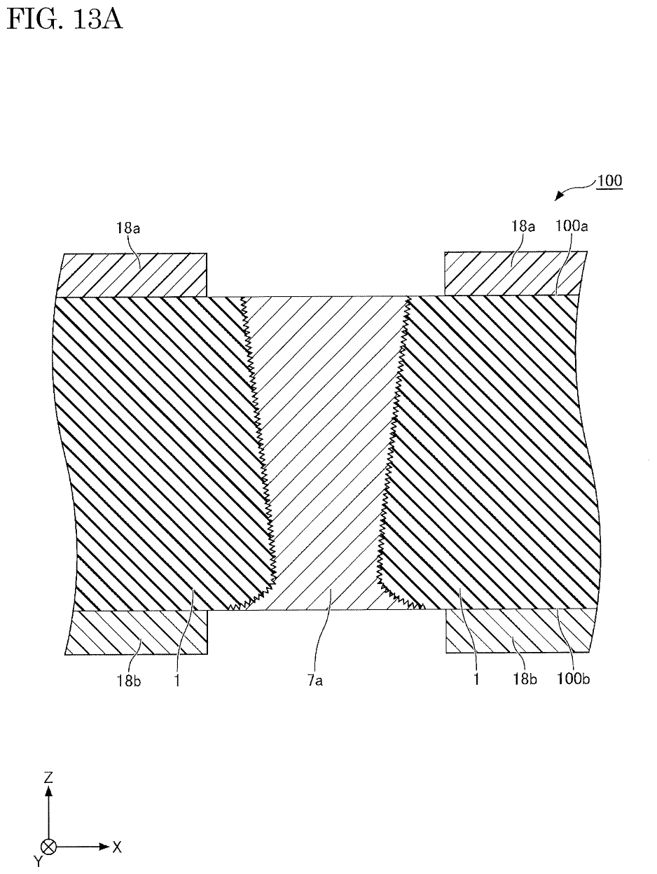

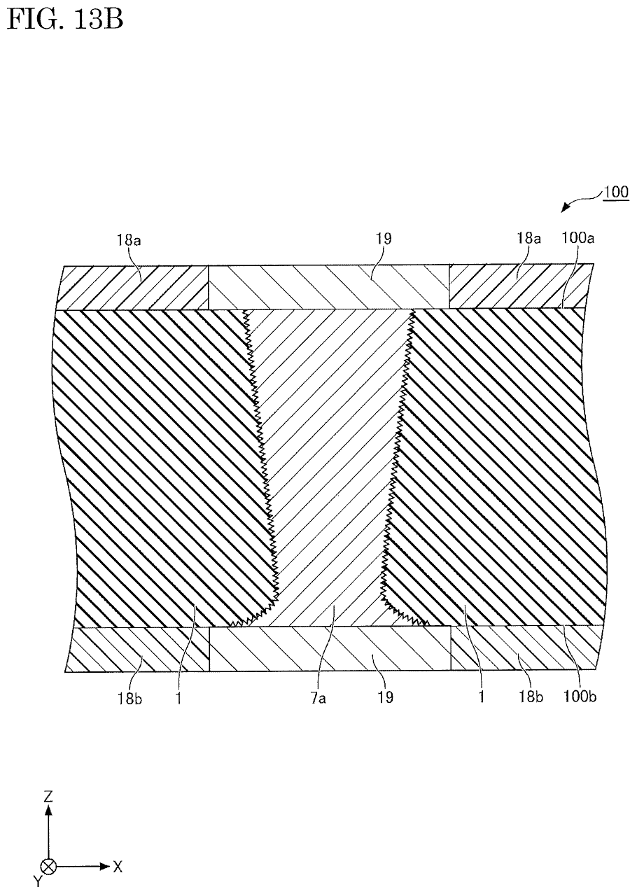

FIG. 13A is a schematic cross-sectional view illustrating an example of disposing a first covering member and a second covering member in the method for manufacturing a ceramic substrate according to the sixth embodiment. FIG. 13B is a schematic cross-sectional view illustrating an example of disposing a second conductive paste in the method for manufacturing a ceramic substrate according to the sixth embodiment.

Examples of the first covering member 18a and the second covering member 18b include a metal mask, a screen mask, and an insulating film (for example, a resist). The first covering member 18a and the second covering member 18b can be the same or can be different from each other. Among these covering members, the metal mask is preferable.

In a case of using a resist as the first covering member 18a and the second covering member 18b, exposure and development are performed using a photolithography method or an etching method in such a region and such a shape that the second conductive paste 19 is to be disposed.

The method for disposing the second conductive paste 19 is not particularly limited. The second conductive paste 19 can be disposed on the surface of the first conductive paste 6 by filling the openings of the first covering member 18a and the second covering member 18b with the second conductive paste 19 by, for example, screen printing, metal mask printing, or injection through a nozzle.

In S35 of disposing a second conductive paste, after disposing the second conductive paste 19 and before sintering, drying the second conductive paste 19 and pressing the dried second conductive paste 19 can be further performed, similarly to S4 of disposing a first conductive paste.

The second conductive paste 19 is not particularly limited, and can be appropriately selected from among known conductive pastes. The second conductive paste 19 can have the same composition as that of the first conductive paste 6, or can have a different composition from the first conductive paste 6. Among these pastes, as the second conductive paste 19, it is preferable to use the same paste as the first conductive paste 6 containing the active metal brazing material described in the method for manufacturing a ceramic substrate according to the first embodiment, and it is more preferable to use the same paste as the first conductive paste 6 containing at least one type of powder 17 selected from the group consisting of the active metal brazing material described in the method for manufacturing a ceramic substrate according to the third embodiment, a copper powder, a silver powder, a powder of an alloy of silver and copper, and a ceramic powder.

### S36 Sintering

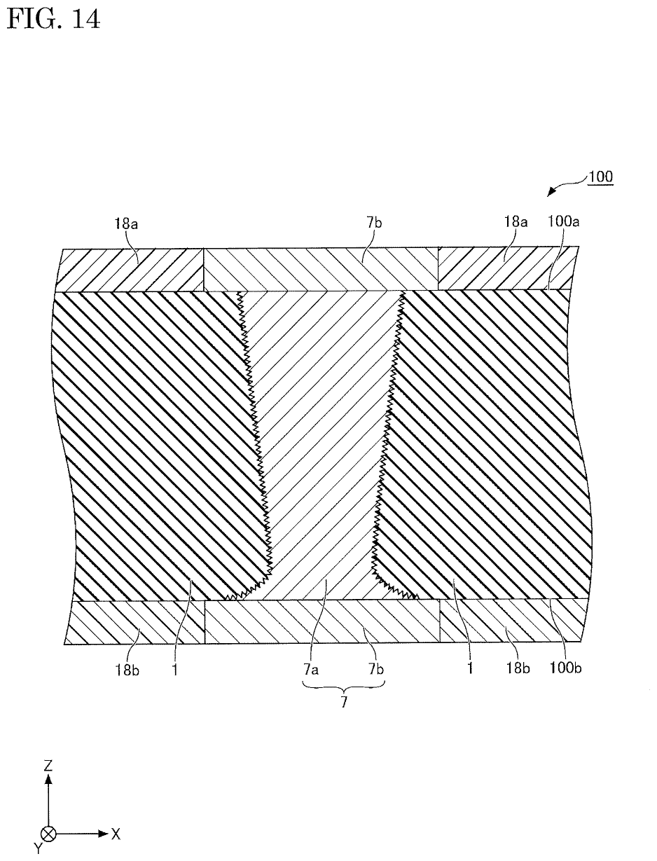

FIG. 14 is a schematic cross-sectional view illustrating an example of sintering in the method for manufacturing a ceramic substrate according to the sixth embodiment.

In S36 of sintering, the first conductive paste 6 and the second conductive paste 19 are sintered. S36 of sintering is performed, so that the ceramic substrate 100 can be obtained, which has the first surface 100a and the second surface 100b on the side opposite to the first surface 100a, includes the through hole 2 that connects the first surface 100a and the second surface 100b, and has the first conductive member 7a produced by sintering the first conductive paste 6 and disposed in the through hole 2, and in which a second conductive member 7b produced by sintering the second conductive paste 19 is disposed on the surface of the first conductive member 7a on the first surface 100a and on the surface of the first conductive member 7a on the second surface 100b.

The same sintering conditions as those in S5 of sintering in the method for manufacturing a ceramic substrate according to the first embodiment can be applied to S36 of sintering. These sintering conditions include the temperature of sintering and the period of time of sintering.

When the composition of the second conductive paste 19 is the same as the composition of the first conductive paste 6, the first conductive member 7a and the second conductive member 7b after being sintered are not distinguished from each other. Even when the composition of the second conductive paste 19 is different from the composition of the first conductive paste 6, each of the first conductive member 7a and the second conductive member 7b after being sintered functions as a conductive member. Therefore, hereinafter, the first conductive member 7a and the second conductive member 7b may be collectively referred to as a “conductive member 7”.

In the method for manufacturing a ceramic substrate according to the sixth embodiment, even when the volume of the first conductive member 7a is reduced by S36 of sintering, since the second conductive member 7b made of the second conductive paste 19 is in contact with the surfaces of the first conductive member 7a, and is disposed in a convex shape on the first surface 100a and the second surface 100b, it is possible to hinder a decrease in dimensional accuracy and to allow the conductive member 7 to have a sufficient thickness.

### Seventh Embodiment

A method for manufacturing a ceramic substrate according to a seventh embodiment is different from the method for manufacturing a ceramic substrate according to the first embodiment in that, in the method for manufacturing a ceramic substrate according to the sixth embodiment, polishing or grinding the first covering member 18a, the second covering member 18b, and the conductive member 7 is further included, in such a manner as to expose, after sintering, the first surface 1a and the second surface 1b of the ceramic plate 1 at the first covering member 18a, the second covering member 18b, and a portion that is covered with the conductive member 7 formed by sintering the first conductive paste 6 and the second conductive paste 19.

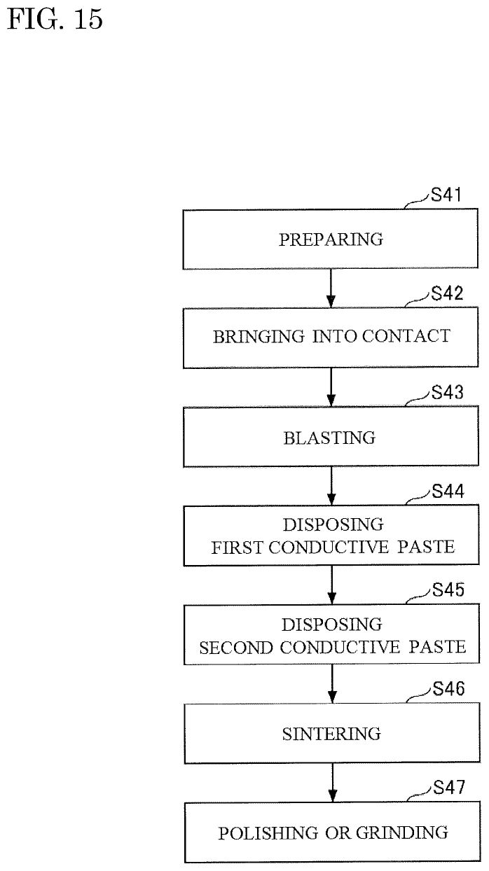

FIG. 15 is a flowchart illustrating an example of preparing a ceramic plate in the method for manufacturing a ceramic substrate according to the seventh embodiment.

### S47 Polishing or Grinding

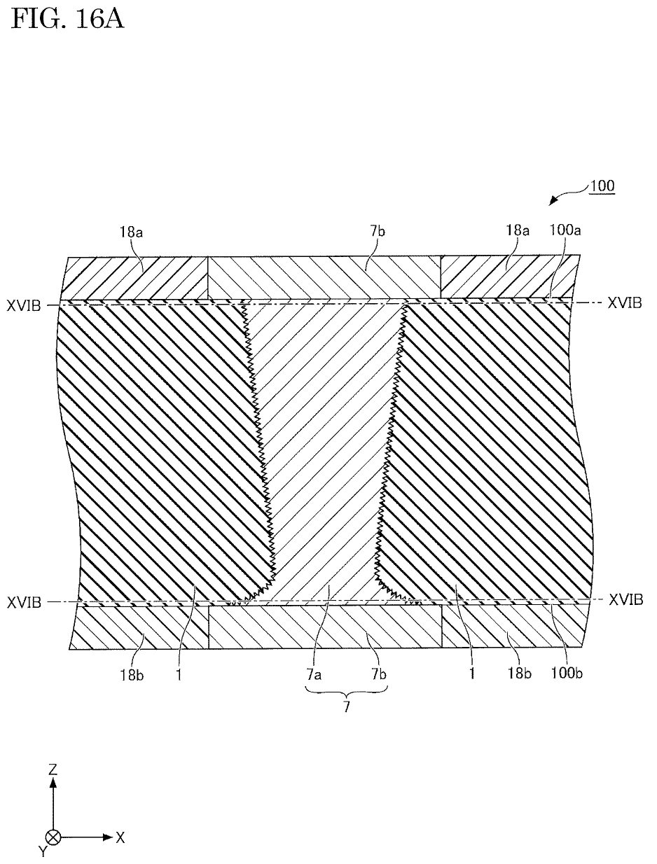

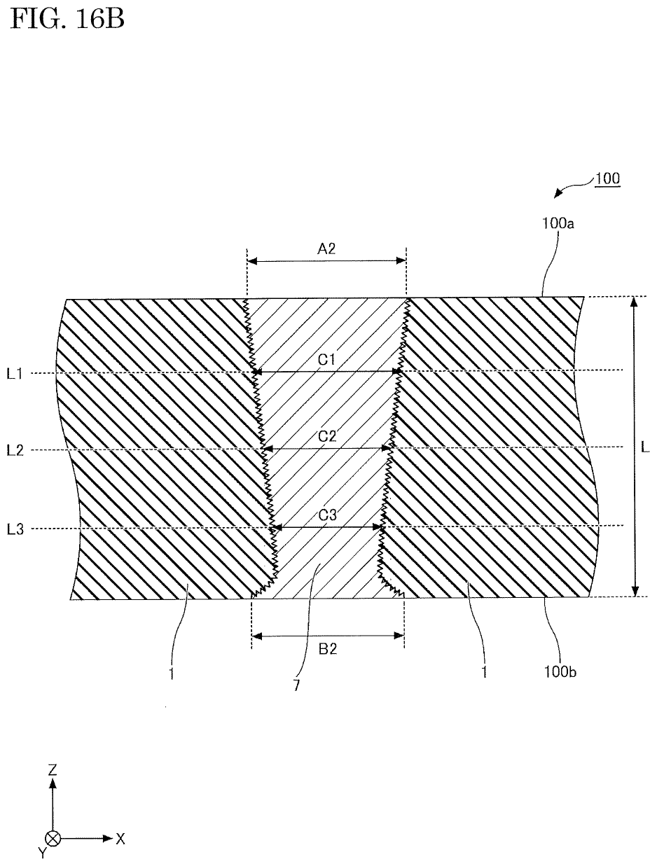

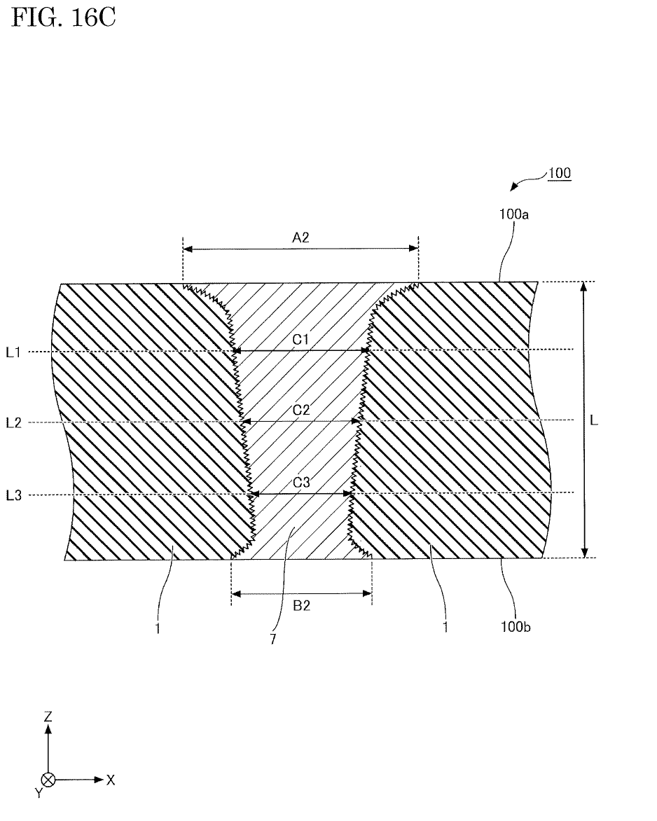

FIG. 16A is a schematic cross-sectional view illustrating an example of polishing or grinding in the method for manufacturing a ceramic substrate according to the seventh embodiment. FIG. 16B is a schematic cross-sectional view illustrating an example of a ceramic substrate after having been polished or ground in the method for manufacturing a ceramic substrate according to the seventh embodiment. FIG. 16C is a schematic cross-sectional view illustrating another example of a ceramic substrate after having been polished or ground in the method for manufacturing a ceramic substrate according to the seventh embodiment, in the method for manufacturing a ceramic substrate according to the fourth embodiment.

The first covering member 18a and the second covering member 18b can be removed by S47 of polishing or grinding.

In S47 of polishing or grinding, the polishing or grinding is performed in such a manner as to expose the first surface 1a and the second surface 1b of the ceramic plate 1. In this case, the polishing or grinding can be performed to remove only the first covering member 18a and the second covering member 18b, but the first surface 1a and the second surface 1b can be partially polished or ground. For example, the first surface 1a and the second surface 1b can be polished or ground along a line XVIB-XVIB. This allows the first surface 100a and the second surface 100b of the ceramic substrate 100 to be smoother, and allows a light-emitting element to be more suitably arranged when the ceramic substrate 100 is used in a light-emitting device.

Further, in S47 of polishing or grinding, the area of the conductive member 7 exposed to the first surface 100a and the second surface 100b can also be adjusted. Since the conductive member 7 has a cross-sectional shape of the through hole 2 formed in S43 of blasting, the conductive member 7 has a tapered shape in which the opening diameter decreases from the second surface 1b gradually in the thickness direction of the ceramic plate 1 in a cross-sectional view. When the conductive member 7 is polished or ground from the second surface 1b, the area of the conductive member 7 exposed to the second surface 1b gradually decreases.

In S47 of polishing or grinding, in order not to impair the effects of the present disclosure, the first surface 1a and the second surface 1b are polished or ground to satisfy C1>C2>C3, A2>C1, and B2>C3, after S47 of polishing or grinding.

The relationship between A2 and B2 can be changed depending on the position to be polished or ground in S47 of polishing or grinding, that is, depending on which position the line XVIB-XVIB is set in the thickness direction (Z-axis direction) of the ceramic substrate 100. When only the second surface 1b is subjected to blasting, A2<B2 can hold in some cases.

In the method for manufacturing a ceramic substrate according to the seventh embodiment, since S47 of polishing or grinding for peeling is performed, when the ceramic substrate 100 is used in a light-emitting device, a light-emitting element can be more suitably disposed on the first surface 100a of the ceramic substrate 100.

### Ceramic Substrate

### Eighth Embodiment

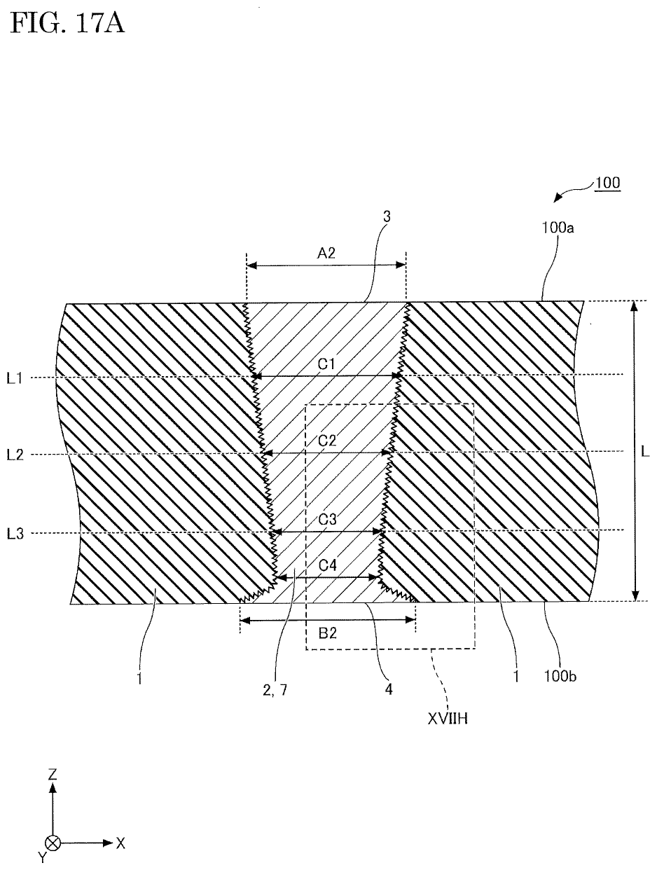

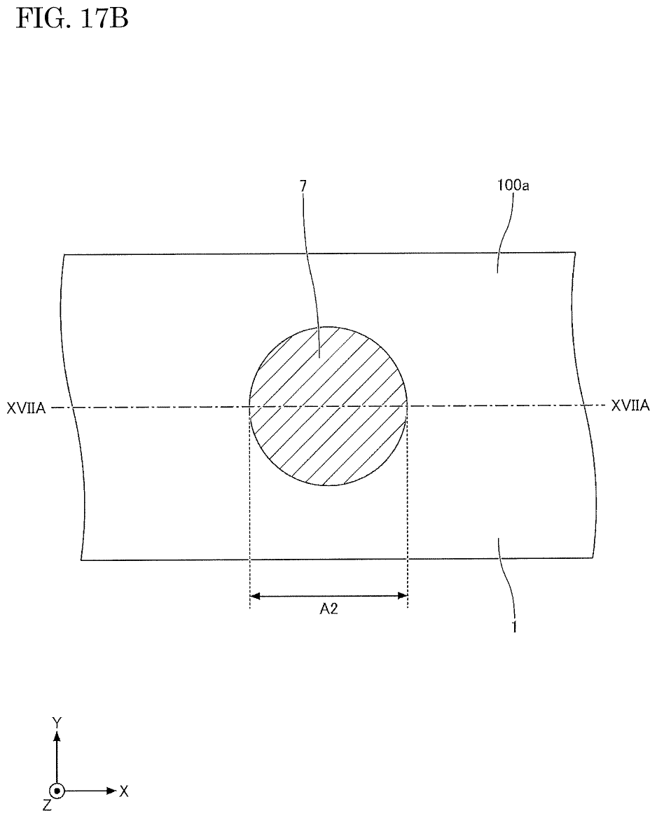

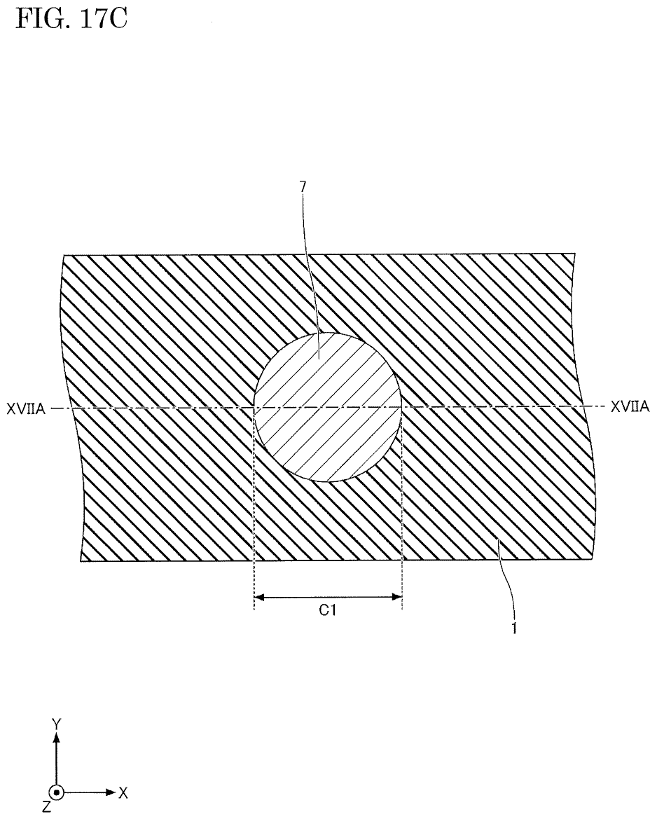

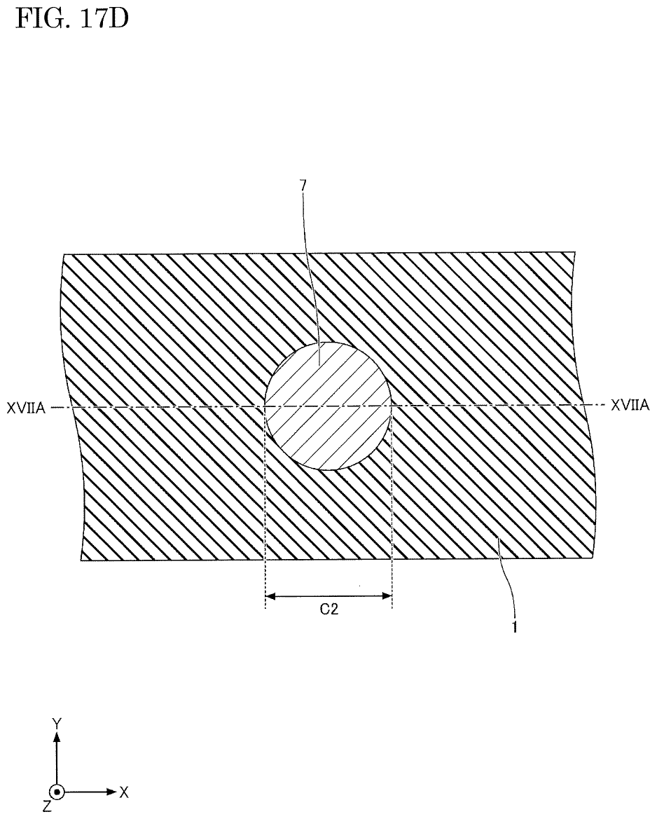

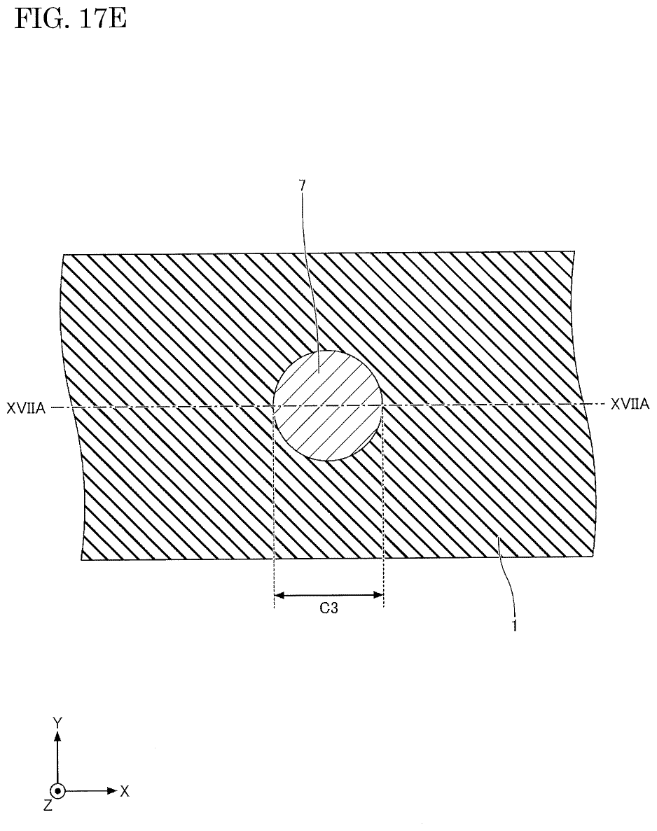

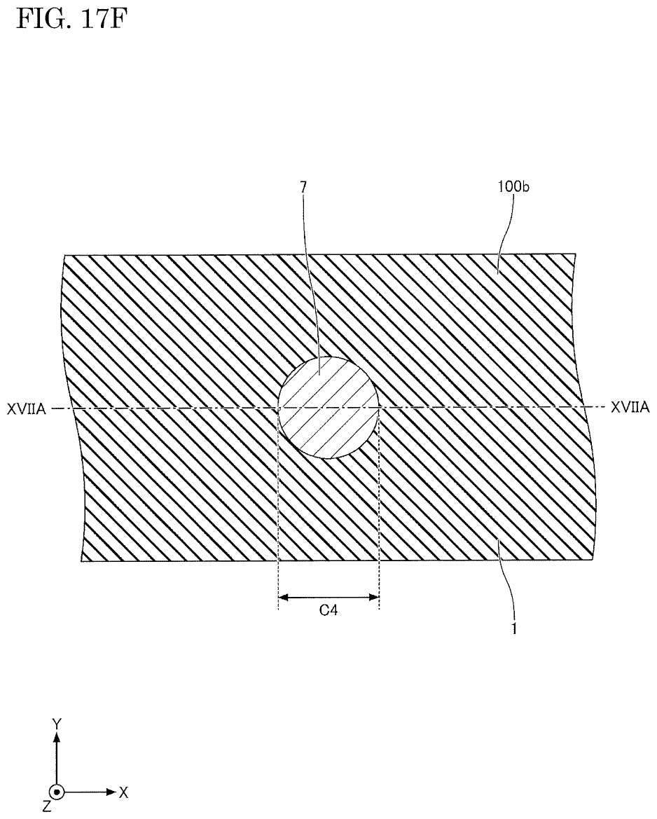

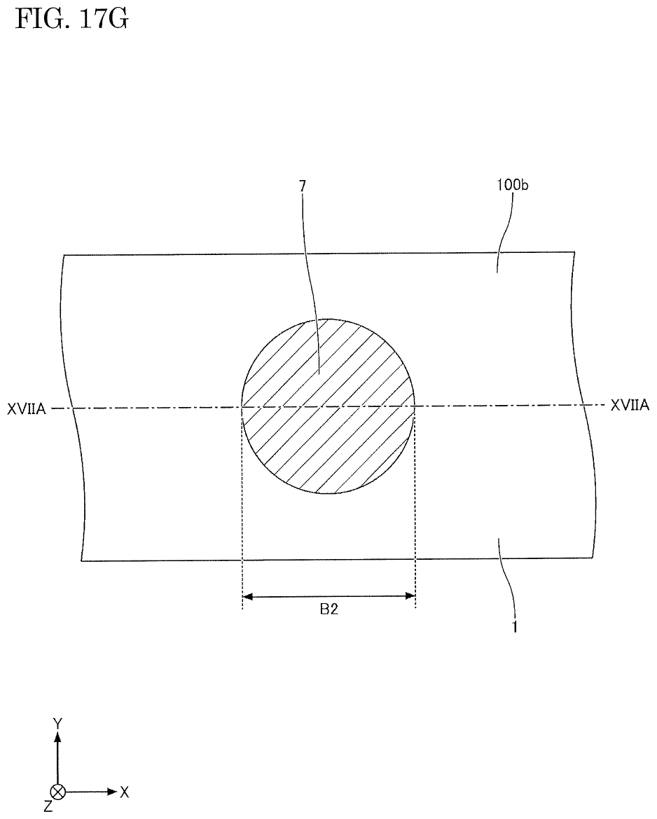

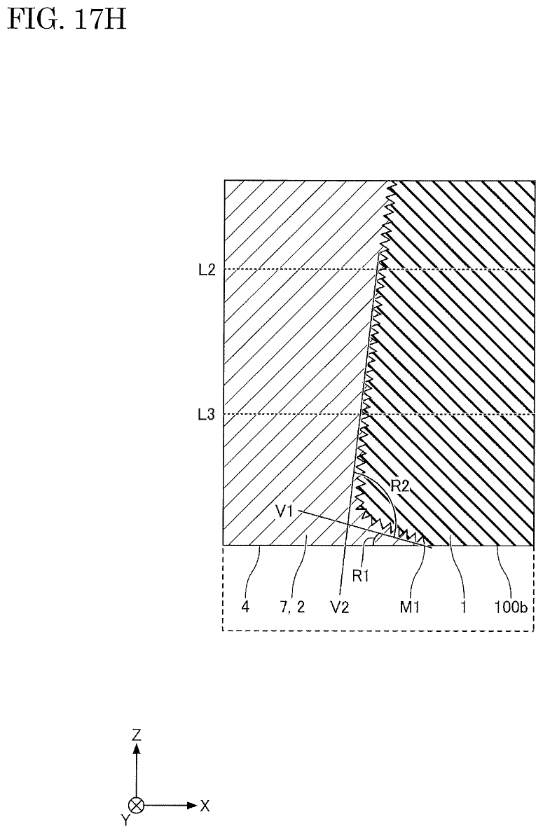

FIG. 17A is a schematic cross-sectional view illustrating an example of a ceramic substrate according to an eighth embodiment. FIG. 17B is a schematic top view of the ceramic substrate in FIG. 17A. FIG. 17C is a schematic cross-sectional view in a direction substantially orthogonal to a thickness direction of the ceramic substrate at a location L1 of the ceramic substrate in FIG. 17A. FIG. 17D is a schematic cross-sectional view in a direction substantially orthogonal to the thickness direction of the ceramic substrate at a location L2 of the ceramic substrate in FIG. 17A. FIG. 17E is a schematic cross-sectional view in a direction substantially orthogonal to the thickness direction of the ceramic substrate at a location L3 of the ceramic substrate in FIG. 17A. FIG. 17F is a schematic cross-sectional view in a direction substantially orthogonal to the thickness direction of the ceramic substrate at a location where the maximum diameter of a through hole in a cross section in the direction substantially orthogonal to the thickness direction of the ceramic substrate is smallest between a second surface of the ceramic substrate in FIG. 17A and the location L3. FIG. 17G is a schematic bottom view of the ceramic substrate in FIG. 17A. FIG. 17A is a schematic cross-sectional view taken along a line XVIIA-XVIIA depicted in FIGS. 17B to 17G. FIG. 17H is an enlarged view of a region XVIIH in FIG. 17A.

A ceramic substrate 100 according to the eighth embodiment includes: a ceramic plate 1 having a first surface 100a and a second surface 100b on a side opposite to the first surface 100a, and including a through hole 2 that connects the first surface 100a and the second surface 100b; and a conductive member 7 disposed inside the through hole 2, in which C1>C2>C3 is satisfied, A2>C1 is satisfied, and B2>C3 is satisfied where a maximum diameter of a first opening 3 of the through hole 2 is defined as A2, the first opening 3 being formed in the first surface 100a, a maximum diameter of a second opening 4 of the through hole 2 is defined as B2, the second opening 4 being formed in the second surface 100b, and an average length between the first surface 100a and the second surface 100b is defined as L, and where a maximum diameter of the through hole 2 in a cross section in a direction substantially orthogonal to a thickness direction of the ceramic substrate 100 at a location of L/4 from the first surface 100a is defined as C1, a maximum diameter of the through hole 2 in a cross section in a direction substantially orthogonal to the thickness direction of the ceramic substrate 100 at a location of L/2 from the first surface 100a is defined as C2, and a maximum diameter of the through hole in a cross section in a direction substantially orthogonal to the thickness direction of the ceramic substrate 100 at a location of 3L/4 from the first surface 100a is defined as C3. The ceramic substrate 100 can further include other configurations as necessary. The ceramic substrate 100 can use the configurations of the method for manufacturing the ceramic substrate 100 according to the above-described first embodiment appropriately with reference to these configurations.

The maximum diameter A2 is preferably in a range of 120 μm to 300 μm, and more preferably in a range of 120 μm to 180 μm. The maximum diameter B2 can also be substantially equal to the maximum diameter A2. The expression “substantially equal” indicates that the maximum diameter B2 is 0.9 times or more and 1.1 times or less the maximum diameter A2. This allows the first opening 3 and the second opening 4 to have substantially the same surface area, allowing simplification of the design for mounting the light-emitting element and the like. On the other hand, even when the surface areas of the first opening 3 and the second opening 4 are substantially equal to each other, since a constriction is formed on the lateral surface of the conductive member 7, the conductive member 7 can still be inhibited from falling off the ceramic plate 1.

The average length L between the first surface 100a and the second surface 100b is not particularly limited and can be appropriately selected in accordance with the purpose, but is preferably in a range of 200 μm to 600 μm, and more preferably in a range of 300 μm to 500 μm.

Between the second surface 100b and the location L3, the maximum diameter of the through hole when the maximum diameter of the through hole 2 in a cross section in the direction substantially orthogonal to the thickness direction of the ceramic substrate 100 is smallest is defined as C4. The average length Lis preferably 2.5 times or more greater than C4, and more preferably 3 times or more greater than C4.

In a cross-sectional view in the thickness direction of the ceramic substrate 100, an interior angle R1 is preferably smaller than 90 degrees, the interior angle R1 being an angle formed at a side of the through hole at an intersection point between the second surface 100b and an imaginary line V1, which passes through a point of contact M1 between the second surface 100b and the inner surface defining the through hole 2 and is an extension of a portion, extending from the second surface 100b, of the inner surface defining the through hole 2. An exterior angle R2 is larger than 90 degrees, the exterior angle R2 being an angle formed at the side opposite to the through hole 2 at the intersection point between the imaginary line V1 and an imaginary line V2, which passes through location L2 and location L3 on the inner surface defining the through hole 2, in the cross-sectional view in the thickness direction of the ceramic substrate 100. When these conditions of the interior angle R1 and the exterior angle R2 are satisfied, the through hole 2 has, in the vicinity of the second opening 4 in the second surface 100b, a tapered shape in which the opening diameter decreases from the second surface 100b gradually in the thickness direction of the ceramic substrate 100 in the cross-sectional view.

When a plurality of through holes 2 are provided, the arrangement of the plurality of through holes 2 in a plan view of the ceramic substrate 100, a pitch between one through hole 2 and other adjacent through holes 2, and the like are not particularly limited, and can be appropriately selected in accordance with the purpose. However, since the maximum diameter B2 of the second opening 4 is 0.90 times or more and 1.1 times or less the maximum diameter A2 of the first opening 3, the pitch between the through hole 2 and other adjacent through holes 2 formed in the first surface 100a can be substantially equal to the pitch between the through hole 2 and other adjacent through holes 2 formed in the second surface 100b. As a result, in the ceramic substrate 100, the distance between the through holes 2 adjacent to each other can be made constant, and the degree of freedom in designing the ceramic substrate 100 increases.

### Ninth Embodiment

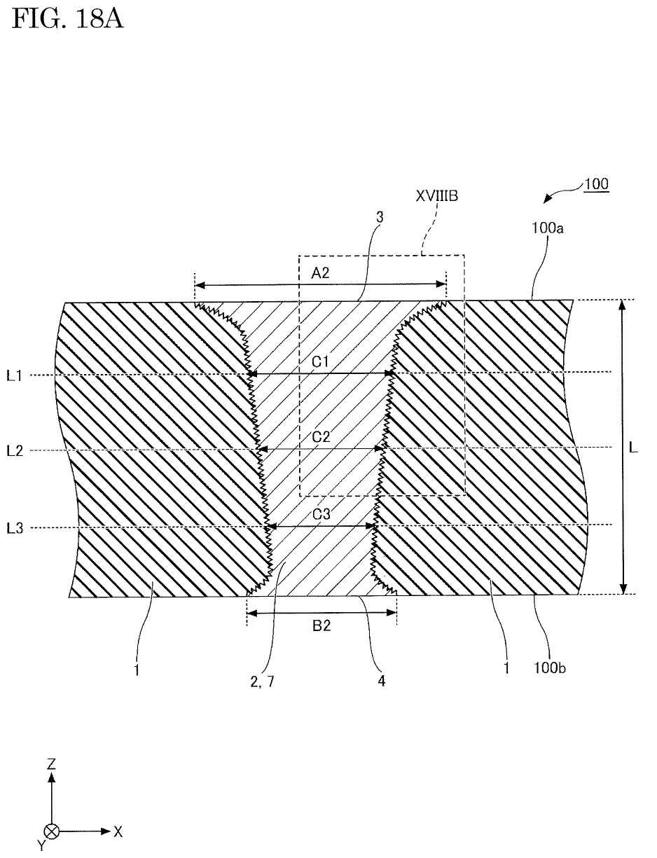

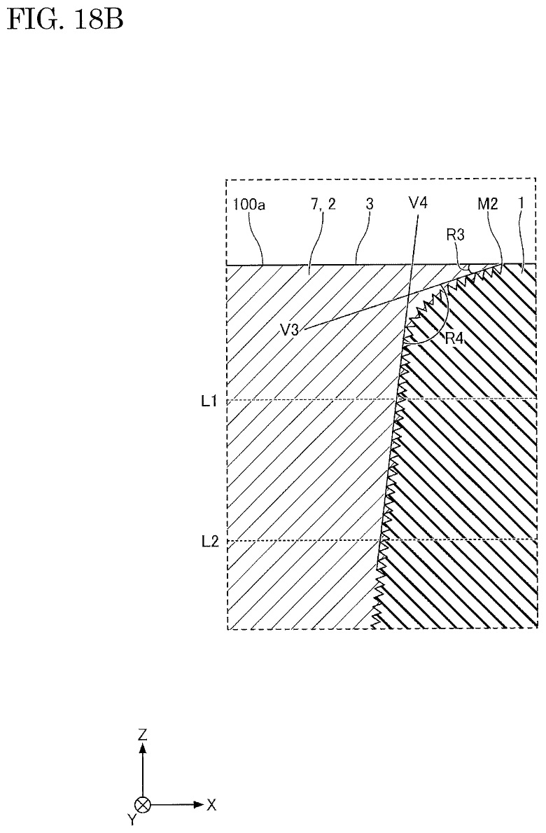

FIG. 18A is a schematic cross-sectional view illustrating an example of a ceramic substrate according to a ninth embodiment. FIG. 18B is an enlarged view of a region XVIIIB in FIG. 18A.

A ceramic substrate 100 according to the ninth embodiment is different from the ceramic substrate 100 according to the first embodiment in that the conductive member 7 has a tapered shape in which the length in the X-axis direction (the length of the conductive member 7 in a direction orthogonal to the thickness direction of the ceramic substrate 100 or the width of the conductive member 7 in a cross-sectional view) decreases from the first surface 100a gradually in the thickness direction of the ceramic substrate 100 in the cross-sectional view.

An interior angle R3 is preferably smaller than 90 degrees, the interior angle R3 being an angle formed at a side of the through hole at an intersection point between the first surface 100a and an imaginary line V3, which passes through a point of contact M2 between the first surface 100a and the inner surface defining the through hole 2 and is an extension of a portion, extending from the first surface 100a, of the inner surface defining the through hole 2 in the cross-sectional view in the thickness direction of the ceramic substrate 100. In addition, an exterior angle R4 is larger than 90 degrees, the exterior angle R4 being an angle formed on the side opposite to the through hole 2 at the intersection point between the imaginary line V3 and an imaginary line V4 passing through location L2 and passing through location L1 on the inner surface defining the through hole 2 in the cross-sectional view in the thickness direction of the ceramic substrate 100. When the interior angle R3 and the exterior angle R4 are satisfied, the through hole 2 has, in the vicinity of the first opening 3 in the first surface 100a, a tapered shape in which the opening diameter decreases from the first surface 100a gradually in the thickness direction of the ceramic plate 1 in the cross-sectional view.

### Light-Emitting Device

FIG. 19 is a schematic cross-sectional view illustrating an example of a light-emitting device according to an embodiment. Constituent elements of a light-emitting device 200 will be described below.

A light-emitting device 200 according to the embodiment includes a ceramic substrate 100 according to the embodiment and a light-emitting element 202 provided with an electrode 205 and disposed on the ceramic substrate 100.

The light-emitting device 200 is a device in which the light-emitting element 202 is disposed on the ceramic substrate 100 to emit light. The number of light-emitting elements 202 can be one or can be more than one. When a plurality of light-emitting elements 202 are provided, the arrangement thereof is not particularly limited, and, for example, the light-emitting elements 202 can be arranged in a line.

In the light-emitting device 200, a light-transmissive member 203 covering a light extraction surface of the light-emitting element 202, a light-reflective member 204 covering a lateral surface of the light-emitting element 202 and a first surface 100a of the ceramic substrate 100, and a metal bump 206 electrically connecting the light-emitting element 202 and a conductive member 7 of the ceramic substrate 100 are disposed as an example.

In the ceramic substrate 100, various wiring-line patterns can be formed depending on applications. However, in the light-emitting device 200 according to the embodiment, the light-emitting element 202 includes a pair of electrodes 205 on the same surface side, and is mounted face-down with the surface having the electrodes 205 facing the first surface 100a of the ceramic substrate 100.

The light-emitting device 200 according to the embodiment can be mounted face-up, in which the pair of electrodes 205 of the light-emitting element 202 is placed on a side opposite to the surface in contact with the ceramic substrate 100 and is connected to the conductive member 7 of the ceramic substrate 100 by wires.

### Light-Emitting Element 202

The light-emitting element 202 includes the pair of electrodes 205, a semiconductor layered body 207, and an element substrate 208.

As an example, the light-emitting element 202 includes the semiconductor layered body 207 on a bottom surface side of the element substrate 208, and includes the pair of electrodes 205 beside the semiconductor layered body 207.

The semiconductor layered body 207 can use any composition in accordance with a desired light emission wavelength, and can use, for example, a nitride semiconductor (InₓAl_{y}Ga_{1-x-y}N, 0≤X, 0≤Y, X+Y≤1) or GaP, which can emit blue or green light, or GaAlAs or AlInGaP, which can emit red light. One type of material among these materials can be used alone, or two or more types of materials can be used in combination. The size and the shape of the light-emitting element 202 can be appropriately selected in accordance with the purpose of use.

As an example, a sapphire substrate or a silicon substrate is used as the element substrate 208.

Each of the electrodes 205 is connected to the corresponding conductive member 7 of the ceramic substrate 100 by the metal bump 206 via a bonding member 209. One of the electrodes 205 is a p-electrode that is disposed at a distance from an n-electrode, the other electrode 205, so as not to be electrically short-circuited with each other. As an example, the electrodes 205 have a configuration in which the p-electrode is disposed at one location, and the n-electrode is disposed at another location, but can have a configuration in which one of the electrodes is disposed at two locations and the other is disposed at another location.

### Light-Transmissive Member 203

The light-transmissive member 203 is disposed on a flat surface side of the element substrate 208, which serves as a light extraction surface. The light-transmissive member 203 is made of, for example, a light-transmissive resin material, and an epoxy resin, a silicone resin, or a resin in which an epoxy resin and a silicone resin are mixed can be used. The light-transmissive member 203 can include a phosphor.

For example, when the light-transmissive member 203 includes a phosphor that absorbs blue light from the light-emitting element 202 and emits yellow light, white light can be emitted. The light-transmissive member 203 can include a plurality of types of phosphors. For example, when the light-transmissive member 203 includes a phosphor that absorbs blue light from the semiconductor layered body 207 and emits green light, and a phosphor that absorbs the blue light and emits red light, white light can also be emitted from the light-emitting element 202.

A phosphor that can be excited by the light emitted from the light-emitting element 202 is used as the phosphor contained in the light-transmissive member 203. One of the specific examples of phosphors described below can be used alone, or a combination of two or more types thereof can be used. Specific examples of the phosphor that can be excited by a blue light-emitting element or an ultraviolet light-emitting element include an yttrium aluminum garnet-based phosphor activated with cerium (for example, Y₃(Al,Ga)₅O₁₂:Ce), a lutetium aluminum garnet-based phosphor activated with cerium (for example, Lu₃(Al,Ga)₅O₁₂:Ce), a nitrogen-containing calcium aluminosilicate-based phosphor activated with europium and/or chromium (for example, CaO—Al₂O₃—SiO₂:Eu), a terbium aluminum garnet-based phosphor (for example, Tb₃(Al,Ga)₅O₁₂:Ce), a silicate-based phosphor activated with europium (for example, (Sr,Ba)₂SiO₄:Eu), a β-sialon phosphor (for example, Si_{6-z}Al_{z}O_{z}N_{8-z}:Eu (0<z≤4.2)), an α-sialon phosphor (for example, Mz(Si,Al)₁₂(O,N)₁₆ (in which 0<z≤2 is satisfied, and M is Li, Mg, Ca, Y, or a lanthanide element other than La and Ce)), a nitride-based phosphor such as a CASN-based phosphor (for example, CaAlSiN₃:Eu) or an SCASN-based phosphor (for example, (Sr,Ca)AlSiN₃:Eu), a potassium fluorosilicate-based phosphor activated with manganese (for example, K₂SiF₆:Mn, K₂(Si,Al)F₆:Mn, 3.5MgO·0.5MgF₂·GeO₂:Mn), a sulfide-based phosphor, and a quantum dot phosphor (for example, perovskite and chalcopyrite). These phosphors are combined with a blue light-emitting element or an ultraviolet light-emitting element, and thus light-emitting devices with various light emission colors (for example, a white-based light-emitting device) can be manufactured. When a light-emitting device is designed to emit white light, the type and the concentration of the phosphor contained in the light-transmissive member 203 are adjusted to emit white light. When such a phosphor is contained in the light-transmissive member 203, the concentration of the phosphor is preferably in a range of about 5% to about 50%.

### Metal Bump 206

The metal bump 206 is a member that electrically connects the electrode 205 and the conductive member 7. The metal bump 206 can be disposed on the electrode 205 side, or can be disposed on the conductive member 7 side. The shape, size, and number of metal bumps 206 can be appropriately set as long as the metal bumps 206 can be disposed within the range of the electrode 205. The size of each of the metal bumps 206 can be appropriately adjusted in accordance with the size of the semiconductor layered body 207, the required light emission power of the light-emitting element, and the like. For example, the metal bump 206 can have a diameter of about several tens of μm to several hundreds of μm.

The metal bump 206 can be made of, for example, Au, Ag, Cu, Al, Sn, Pt, Zn, Ni, or an alloy thereof. The metal bump 206 can be formed of, for example, a stud bump known in the related art. The stud bump can be formed by a stud bump bonder, a wire bonding apparatus, or the like. The metal bump 206 can also be formed by a method known in the art, such as electroplating, electroless plating, vapor deposition, or sputtering.

As an example, the metal bump 206 is bonded via the bonding member 209. Examples of the bonding member 209 used herein include solders such as tin-bismuth based solders, tin-copper based solders, tin-silver based solders, and gold-tin based solders, eutectic alloys such as alloys containing Au and Sn as main materials, alloys containing Au and Si as main materials, and alloys containing Au and Ge as main materials, paste materials of silver, gold, palladium, and the like, anisotropic conductive materials such as ACP and ACF, brazing materials made of low melting point metals, and conductive adhesives and conductive composite adhesives of combinations of these materials.

### Light-Reflective Member 204

The light-reflective member 204 is a member having light reflectivity. The light-reflective member 204 is disposed to cover the first surface 100a of the ceramic substrate 100 and to cover the lateral surface of the light-emitting element 202. The light-reflective member 204 is disposed to expose the light extraction surface of the light-emitting element 202 and to be flush with the light-transmissive member 203 of the light-emitting element 202. As an example, the light-reflective member 204 is also disposed between the lower surface of the light-emitting element 202 and the first surface 100a of the ceramic substrate 100.

The light-reflective member 204 preferably has a high reflectance in order to effectively utilize light from the light-emitting element 202. The light-reflective member 204 is preferably white. The reflectance of the light-reflective member 204 is, for example, preferably 90% or more, and more preferably 94% or more to the wavelength of the light emitted from the light-emitting element 202.

Examples of a resin used for the light-reflective member 204 include thermoplastic resins such as acrylic resin, polycarbonate resin, cyclic polyolefin resin, polyethylene terephthalate resin, polyethylene naphthalate resin, and polyester resin, and thermosetting resins such as epoxy resin and silicone resin. As a light-diffusing material, for example, a known material, such as titanium oxide, silicon oxide, aluminum oxide, zinc oxide, or glass, can be used.

Although the light-emitting device 200 uses one unit of light-emitting element 202 as a control unit to control brightness and turning on/off, the number of light-emitting elements 202 included in one unit can be one or can be more than one. For example, four light-emitting elements 202 arranged in one row and four columns or arranged in two rows and two columns, or nine light-emitting elements 202 arranged in three rows and three columns can be used as one unit. Thus, the number of light-emitting elements 202 is not limited.

In the light-emitting device according to the embodiment of the present disclosure, the maximum diameter A2 of the first opening 3 of the through hole 2 formed in the first surface 100a, and the maximum diameter B2 of the second opening 4 of the through hole 2 formed in the second surface 100b satisfy A2>B2 in the ceramic substrate 100. The through hole 2 is filled with the conductive member 7. Accordingly, the exposed portions of the conductive member 7 on the first surface 100a and the second surface 100b of the ceramic substrate 100 also satisfy A2>B2. As a result of this, when the light-emitting element is mounted on the first surface 100a, terminals can be spaced apart from each other on the second surface 100b, thereby making it possible to suppress the occurrence of short-circuiting by solder connection or the like that is generally used.

### Application Example of Light-Emitting Device

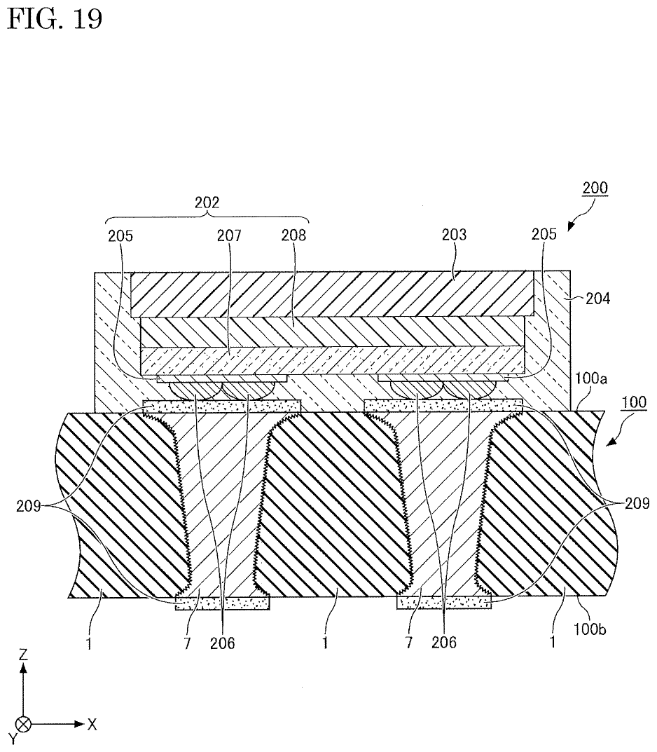

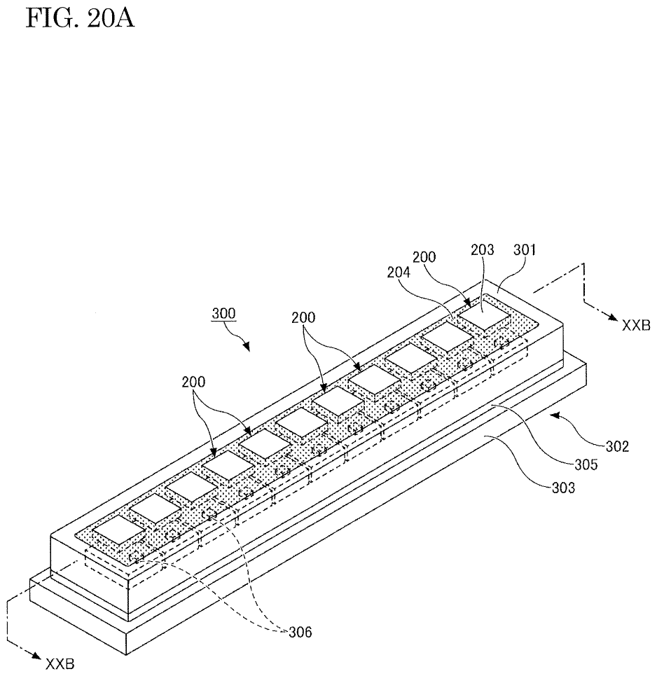

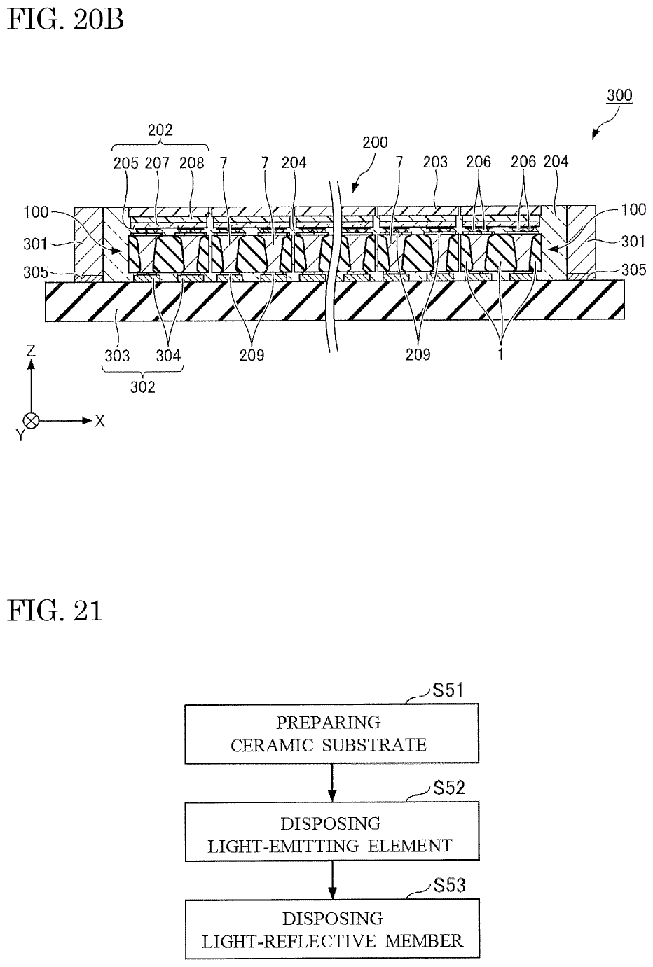

FIG. 20A is a perspective view illustrating an application example of the light-emitting device according to the embodiment. FIG. 20B is a cross-sectional view taken along a line XXB-XXB in FIG. 20A. FIG. 20B does not illustrate a part of the configuration in FIG. 20A.

A light-emitting module 300 can include a plurality of light-emitting devices 200 (11 light-emitting devices 200 in FIG. 20A) in a line, or the 11 light-emitting devices 200 can be mounted on one ceramic substrate 100. A configuration of the light-emitting module 300 is described below.

The light-emitting module 300 includes 11 light-emitting devices 200 in a line, the light-reflective member 204 on the outer periphery of the light-emitting devices 200, and a frame body 301 outside of the light-reflective member 204, in which a module substrate 302 is connected to a surface of the ceramic substrate 100 on the side opposite to the first surface 100a.

The frame body 301 is a member configured to surround the light-reflective member 204 covering the plurality of light-emitting devices 200. The frame body 301 is formed in a rectangular annular shape that is, for example, rectangular in a plan view, and surrounds the periphery of the light-reflective member 204.

The frame body 301 can be formed using a frame-shaped member made of metal, alloy, or ceramic. Examples of the metal include Fe, Cu, Ni, Al, Ag, Au, Pt, Ti, W, and Pd. Examples of the alloy include an alloy including at least one selected from the group consisting of Fe, Cu, Ni, Al, Ag, Au, Pt, Ti, W, and Pd.

A resin material can be used as the frame body 301. In this case, the above-mentioned metal, alloy, or ceramic member can be embedded in the frame body 301 made of the resin material, or a part of the frame body 301 can be made of a resin material and another part of the frame body 301 can be made of a metal, alloy, or ceramic member.

The module substrate 302 is a member on which the light-emitting device 200 is placed, and electrically connects the light-emitting device 200 to the outside. The module substrate 302 is formed in a substantially rectangular shape in a plan view, for example. The module substrate 302 includes a substrate portion 303 and a wiring board portion 304.

As a material of the substrate portion 303, for example, an insulating material is preferably used, and a material that is less likely to transmit light emitted from the light-emitting element 202, external light, and the like is preferably used. Examples of the material of the substrate portion 303 include ceramics such as aluminum oxide, aluminum nitride, and mullite, thermoplastic resins such as polyamide, polyphthalamide, polyphenylene sulfide, and liquid crystal polymer, and resins such as an epoxy resin, a silicone resin, a modified epoxy resin, a urethane resin, and a phenol resin. Among these, as the material of the substrate portion 303, a ceramic having superior heat dissipation characteristics is preferably used.

The wiring board portion 304 is formed on the substrate portion 303 at a position facing the conductive member 7 on a surface of the ceramic substrate 100 of the light-emitting device 200 on the side opposite to the first surface 100a. Examples of the material of the wiring board portion 304 include those exemplified as the material used for the conductive member 7.

The module substrate 302 is bonded to the frame body 301 via a conductive adhesive 305, and is disposed such that the conductive member 7 and the wiring board portion 304 are bonded to each other. As the conductive adhesive 305, for example, a eutectic solder, a conductive paste, or a bump can be used. In the light-emitting device 200, a protective element 306 is disposed on the ceramic substrate 100 in parallel with each light-emitting element 202.

Since the light-emitting module 300 is configured as described above, it is driven as follows. That is, in the light-emitting module 300, a current is supplied from an external power supply to each of the light-emitting elements 202 via the wiring board portion 304, the conductive member 7, and the electrodes 205, so that the light-emitting elements 202 emit light. Of the light emitted from the light-emitting element 202, light traveling upward is extracted to the outside above the light-emitting device 200 via the light-transmissive member 203. Light traveling downward is reflected by the ceramic substrate 100 and is extracted to the outside of the light-emitting device 200 via the light-transmissive member 203. Light traveling between the light-emitting element 202 and the frame body 301 is reflected by the light-reflective member 204 and the frame body 301, and is extracted to the outside of the light-emitting device 200 via the light-transmissive member 203. Light traveling between the light-emitting elements 202 is reflected by the light-reflective member 204 and is extracted to the outside of the light-emitting device 200 via the light-transmissive member 203. At this time, a space between the light-transmissive members 203 is reduced (to, for example, equal to or less than 0.2 mm), so that when the light-emitting module 300 is used, for example, for a light source of a vehicle headlight, the configuration of an optical system can be simplified and reduced in size.

When the light-emitting module 300 is manufactured, the light-emitting devices 200 are arranged side by side on a sheet member, the frame body 301 is disposed around the light-emitting devices 200, and in this state, a space surrounded by the frame body 301 and the sheet member is filled with the light-reflective member 204, thereby disposing the light-reflective member 204. Subsequently, the light-emitting devices 200 supported by the frame body 301 and the light-reflective member 204 are disposed on the module substrate 302, on which the wiring board portions 304 and the conductive adhesive 305 are disposed, to electrically connect the conductive members 7 and the wiring board portions 304. The light-emitting module 300 is thereby manufactured.

### Method for Manufacturing Light-Emitting Device

A method for manufacturing the light-emitting device according to the embodiment includes preparing the ceramic substrate 100 manufactured by the method for manufacturing the ceramic substrate 100 according to the embodiment, and disposing the light-emitting element 202 including the electrodes 205 on the ceramic substrate 100. The electrodes 205 and the conductive member 7 are electrically connected.

FIG. 21 is a flowchart illustrating an example of the method for manufacturing the light-emitting device according to the embodiment. The method for manufacturing the light-emitting device according to the embodiment includes, for example, disposing the light-reflective member.

### S51 Preparing Ceramic Substrate

In S51 of preparing a ceramic substrate 100, the ceramic substrate 100 according to the embodiment is prepared.

The ceramic substrate 100 can include a plurality of regions in which the light-emitting elements 202 are disposed, and can have a size to be singulated into individual light-emitting devices 200 after the light-reflective member 204 is disposed, or can have a size for each light-emitting device 200.

### S52 Disposing Light-Emitting Element

In S52 of disposing a light-emitting element, the light-emitting element 202 including the electrodes 205 is disposed on the ceramic substrate 100. In S52 of disposing a light-emitting element, the electrodes 205 of the light-emitting element 202 are connected to the bonding members 209 disposed on the conductive members 7 by using the metal bumps 206. The light-emitting element 202 with the light-transmissive member 203 connected to the element substrate 208 in advance is disposed. When the light-transmissive member 203 is bonded to the element substrate 208, a light-transmissive bonding material is used.

### S53 Disposing Light-Reflective Member

In S53 of disposing a light-reflective member, the light-reflective member 204 is disposed to cover the first surface 100a of the ceramic substrate 100 and also cover the lateral surface of the light-emitting element 202. The light-reflective member 204 is disposed on the ceramic substrate 100 in such a manner as to surround the light-emitting element 202 and expose the upper surface of the light-transmissive member 203 serving as the light extraction surface of the light-emitting element 202. The light-reflective member 204 is disposed to have a rectangular shape in a plan view.

In the method for manufacturing the light-emitting device according to the embodiment, a singulation operation is performed as necessary after S53 of disposing a light-reflective member. For the light-emitting devices 200, one unit of the light-emitting device 200 is set in advance by the number of light-emitting elements 202 used therein. Therefore, when a plurality of light-emitting devices 200 are manufactured together, the singulation operation is performed. When the singulation operation is performed, the plurality of light-emitting devices 200 are produced by cutting in a lattice pattern. Examples of the cutting method include methods using a disk-shaped rotating blade, an ultrasonic cutter, and a laser light irradiation blade.

### EXAMPLES

Hereinafter, the present invention will be described in detail with reference to Examples. However, the present invention is not limited to Examples described below.

### Example 1

A ceramic substrate 100 of Example 1 was manufactured by applying S21 of preparing a ceramic substrate in FIG. 8 as the method for manufacturing a ceramic substrate according to the fifth embodiment to the flowchart illustrated in FIG. 12 as the method for manufacturing a ceramic substrate according to the sixth embodiment.

### S21-1 Preparing Ceramic Plate Not Including Through Hole

In S21-1 of preparing a ceramic plate not including a through hole, a ceramic plate 1 having a flat plate shape, having a thickness of 370 μm, and containing aluminum nitride as a main material, but not including a through hole was prepared.

### S21-2 Forming Through Hole

In S21-2 of forming a through hole, a through hole 2 was formed by irradiation with fiber laser light Z (wavelength: 1070 nm, power: 1000 W, frequency: 100 Hz, irradiation time: 3 milliseconds) from the first surface 1a of the ceramic plate 1.

S32 Bringing into Contact

In S32 of bringing into contact, the ceramic plate 1 having the through holes 2 formed therein was immersed in a solution of 3.0 mol/L potassium hydroxide as an etchant, and was left at 80° C. under atmospheric conditions for 90 minutes.

### S33 Blasting

S33 of blasting was carried out in accordance with S3 of blasting described in the fourth embodiment. To be specific, the abrasive 10 was supplied from the second surface 1b and the first surface 1a of the ceramic plate 1, and the through hole 2 was subjected to blasting.

### S34 Disposing First Conductive Paste

In S34 of disposing a first conductive paste, an active brazing material containing the eutectic powder 11 of silver and copper, the active metal powder 12, the solvent 13, and the inorganic filler 14 was used as the first conductive paste 6, and the first conductive paste 6 was disposed by filling the through hole 2 with the first conductive paste 6 by screen printing in such a manner as to have substantially the same surface heights as the first surface 1a and the second surface 1b of the ceramic plate 1. The active brazing material containing 75 mass % of the eutectic powder 11, 10 mass % of the active metal powder 12, 10 mass % of the solvent 13, and 5 mass % of the inorganic filler 14 relative to the total mass of the active brazing material was used.

### S35 Disposing Second Conductive Paste

In S35 of disposing a second conductive paste, metal masks serving as the first covering member 18a and the second covering member 18b were disposed on the first surface 1a and the second surface 1b of the ceramic plate 1, respectively, and the second conductive paste 19 having the same composition as the first conductive paste 6 used in S34 of disposing a first conductive paste was disposed by metal mask printing. Thereafter, the ceramic plate 1 was put in an electric furnace set at 100° C. to dry the first conductive paste 6 and the second conductive paste 19 for 15 minutes.

### S36 Sintering

In S36 of sintering, the ceramic plate 1 after having undergone S35 of disposing a second conductive paste was sintered in a vacuum furnace at 10-6 Pa under the condition that the ceramic plate 1 was maintained at a maximum temperature of 850° C. for 15 minutes.

### Evaluation 1

### Observation of Ceramic Plate 1 and Through Hole 2

In Example 1, the ceramic plate 1 after having undergone S32 of bringing into contact, and the ceramic plate 1 after having undergone S33 of blasting were cut in the thickness direction by laser light irradiation, and observed with a scanning electron microscopy (SEM).

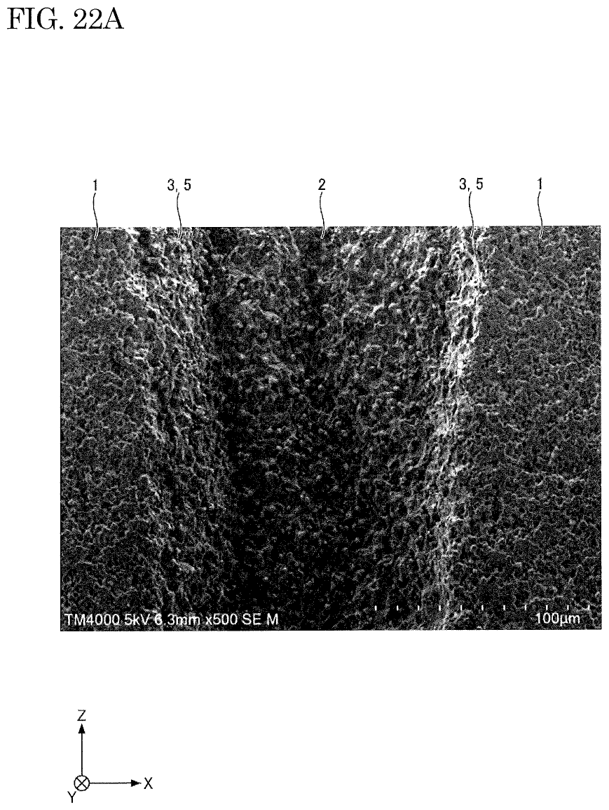

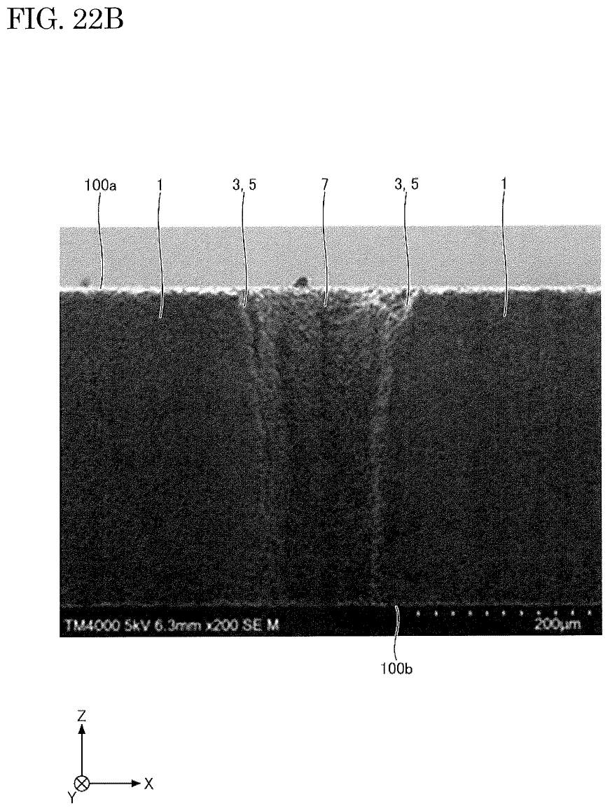

FIG. 22A is a SEM cross-sectional observation image of the through hole 2 observed at a magnification of 500 after having undergone S32 of bringing into contact in Example 1. The scale bar is 100 μm. FIG. 22B is a SEM cross-sectional observation image depicting the entirety of the ceramic plate 1 after having undergone S32 of bringing into contact in Example 1. The scale bar is 200 μm.

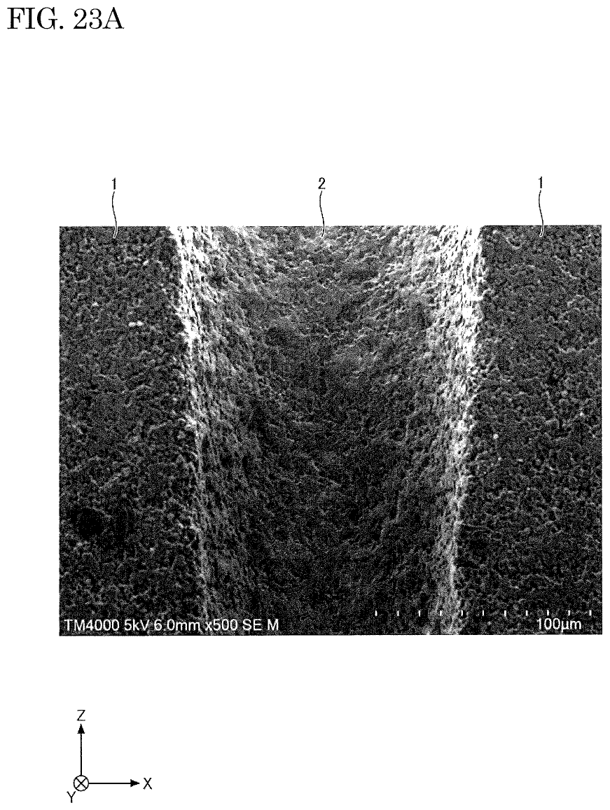

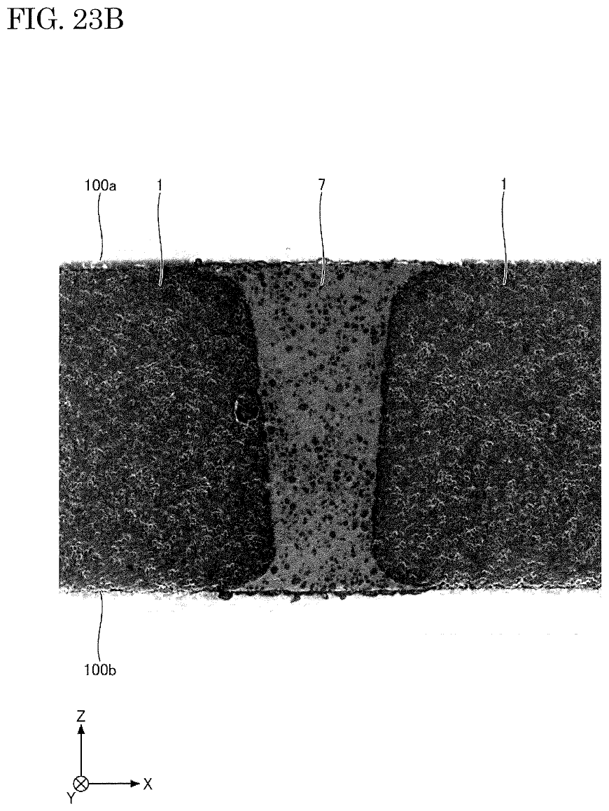

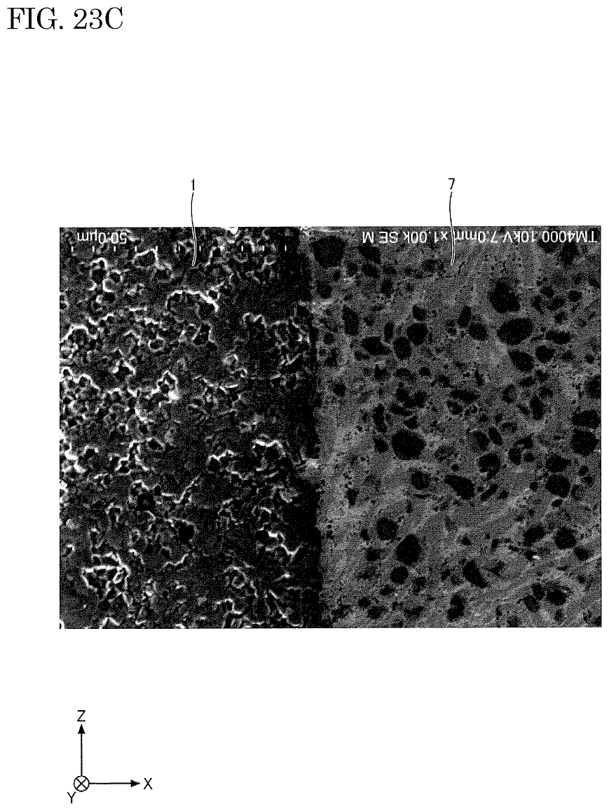

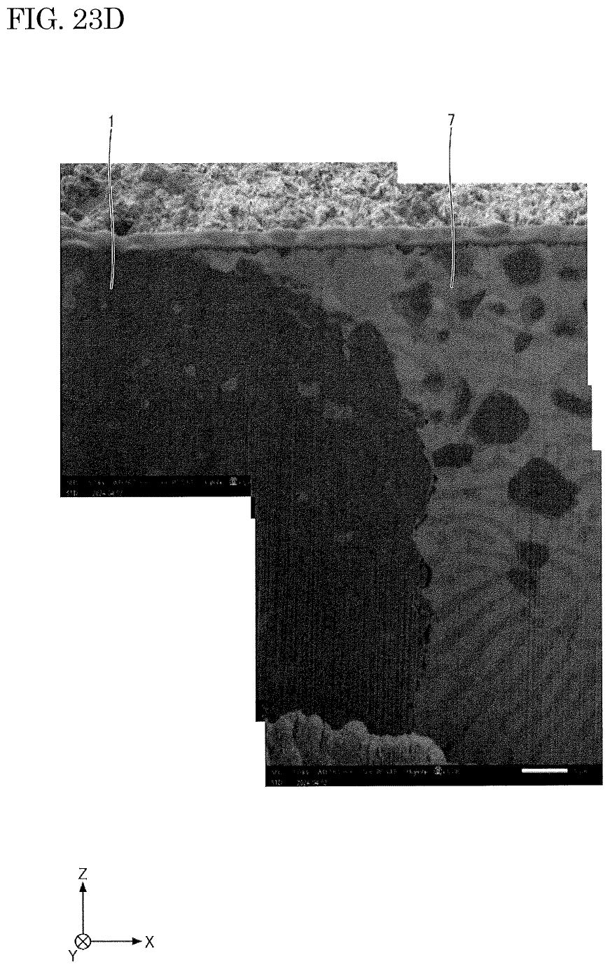

FIG. 23A is a SEM cross-sectional observation image of the through hole 2 observed at a magnification of 500 after having undergone S33 of blasting in Example 1. The scale bar is 100 μm. FIG. 23B is a SEM cross-sectional observation image depicting the entirety of the ceramic plate 1 after having undergone S33 of blasting in Example 1. The scale bar is 200 μm. FIG. 23C is a partially enlarged image of a SEM cross-sectional observation image of the through hole 2 after having undergone S33 of blasting in Example 1. The scale bar is 50 μm. FIG. 23D is a partially enlarged image of a focused ion beam-SEM (FIB-SEM) cross-sectional observation image of the through hole 2 after having undergone S33 of blasting in Example 1. The scale bar is 5 μm.

From FIGS. 22A and 22B, it has been found that, after having undergone S32 of bringing into contact, cracks were generated in the ceramic plate 1 near the inner surface defining the through hole 2, and damage was observed (the damaged layer 5 was present). On the other hand, from FIGS. 23A to 23D, after having undergone S33 of blasting, the damaged layer 5 was removed, and thus the ceramic plate 1 free of cracks was obtained. After having undergone S33 of blasting, C1>C2>C3, A2>C1, and B2>C3 were satisfied.

### Evaluation 2

### Simulation of Stress on Ceramic Plate 1 in S36 of Sintering

Based on ceramic plates 1 of Design 1 and Design 2 described below, simulation was performed under the following analysis conditions.
(Design 1) Ceramic Plate 1 after S21-2 of Forming Through Hole
(Design 2) Ceramic Plate 1 after S33 of Blasting in Example 1
(Analysis Conditions) The temperature is raised from 25° C. to 790° C. in one hour, the first conductive paste is fired at 790° C., and then the temperature is returned to 25° C. in one hour.

The melting point of the eutectic of silver and copper is about 780° C., and a complete melting type paste solidifies while the temperature is lowered from 780° C. In consideration of this, when the temperature returned from 780° C. to 25° C., the eutectic of silver and copper was assumed to be a solid, and the stress due to a difference in linear expansion coefficient from aluminum nitride as the main material of the ceramic plate 1 was calculated.

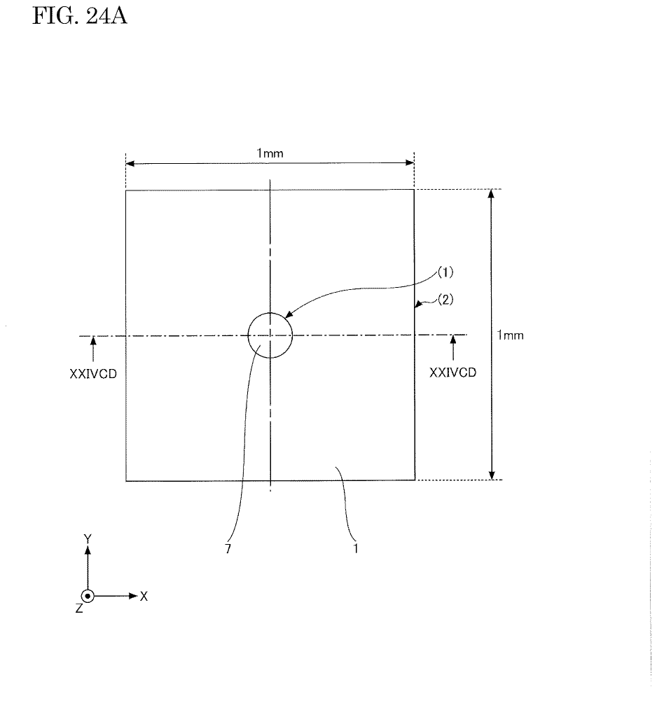

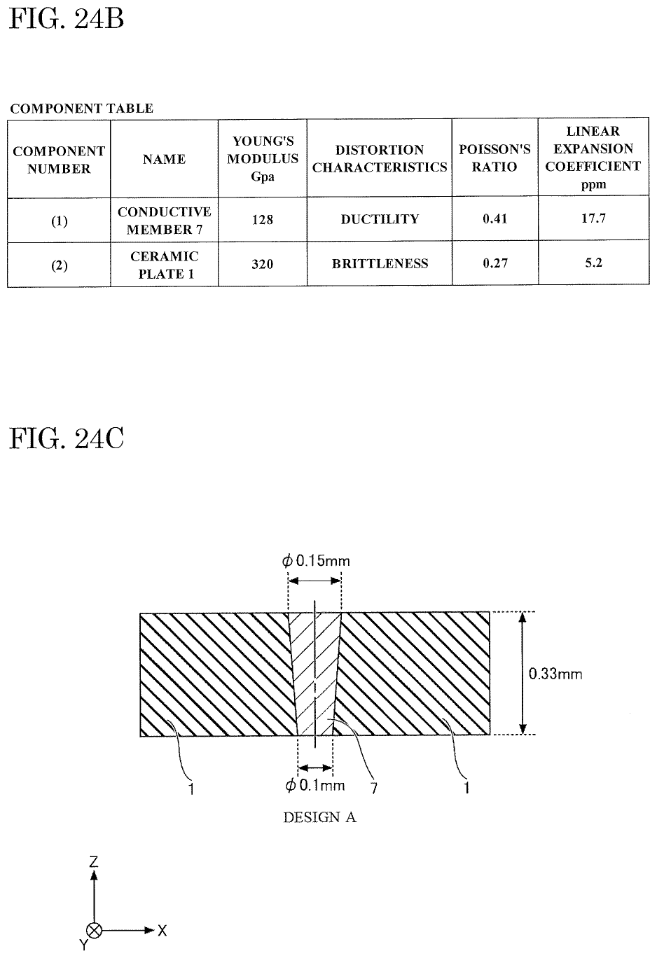

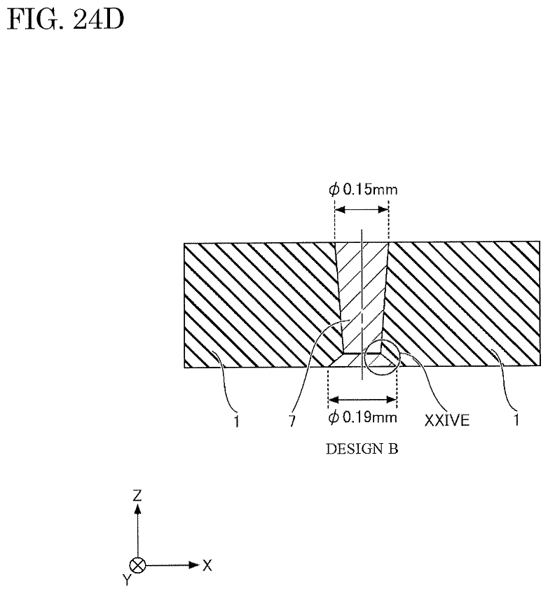

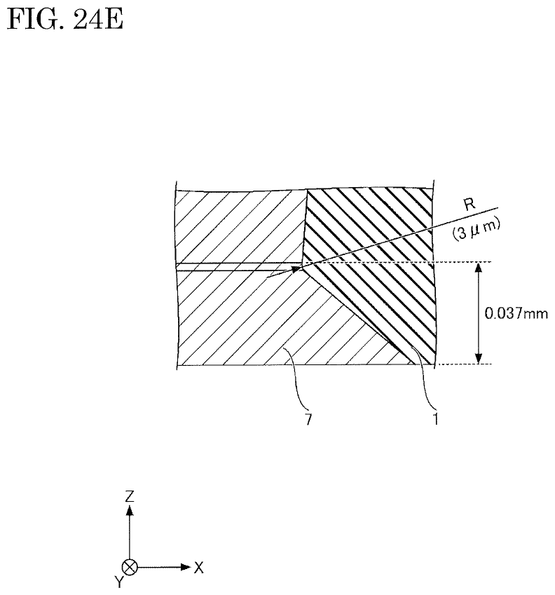

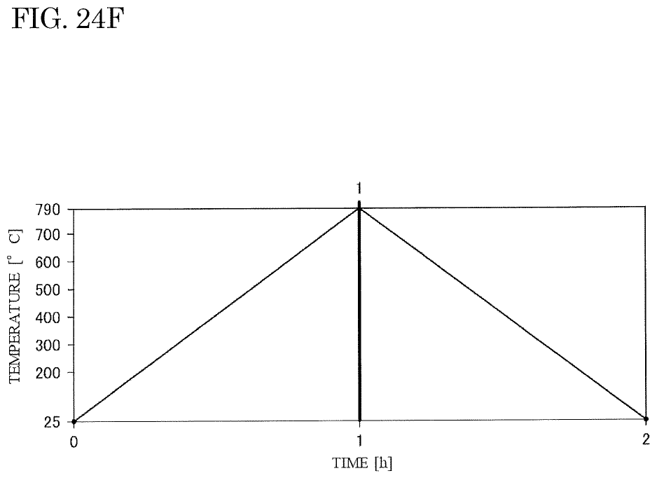

FIG. 24A is a top view of a design drawing of the ceramic plate 1. In FIG. 24A, (1) and (2) indicate component numbers for the simulation. FIG. 24B is a table depicting simulation condition values of a component number (1) and a component number (2) in FIG. 24A. FIG. 24C is a cross-sectional view taken along a line XXIVCD-XXIVCD in FIG. 24A based on “Design 1”. FIG. 24D is a cross-sectional view taken along the line XXIVCD-XXIVCD in FIG. 24A based on “Design 2”. FIG. 24E is an enlarged cross-sectional view of a region XXIVE in FIG. 24D. FIG. 24F is a graph depicting a temperature condition of the simulation. The temperature rises from 25° C. to 780° C. in one hour, and then returns to 25° C. in one hour.

In the simulation, it was assumed that S47 of polishing or grinding the first surface 1a and the second surface 1b of the ceramic plate 1 was not performed. The conductive member 7 was assumed to be a eutectic of silver and copper, and a theoretical value of copper was used for calculation. That is, the TiN layer (the nitride coating film 16b) and the Ag layer were omitted in the theoretical values. Further, no creep was assumed to be present, and heat dissipation analysis was not performed.

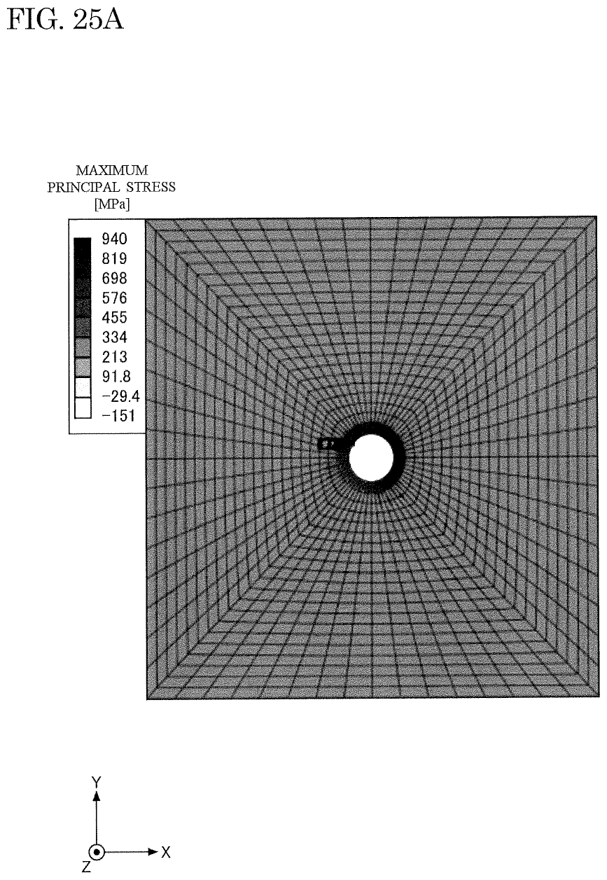

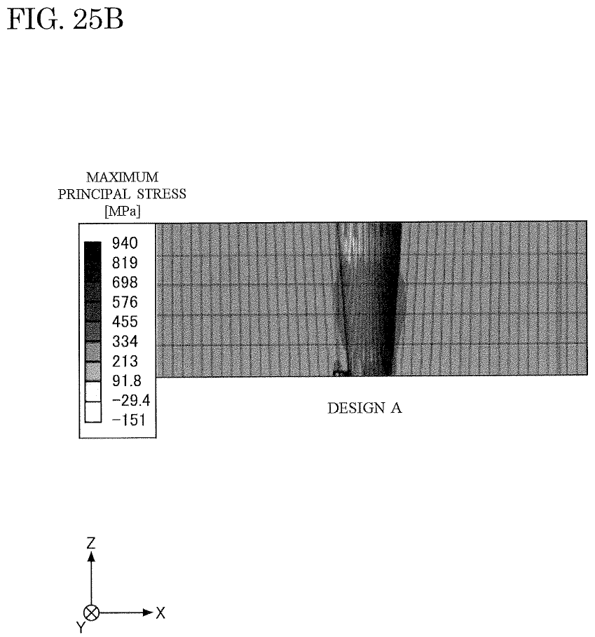

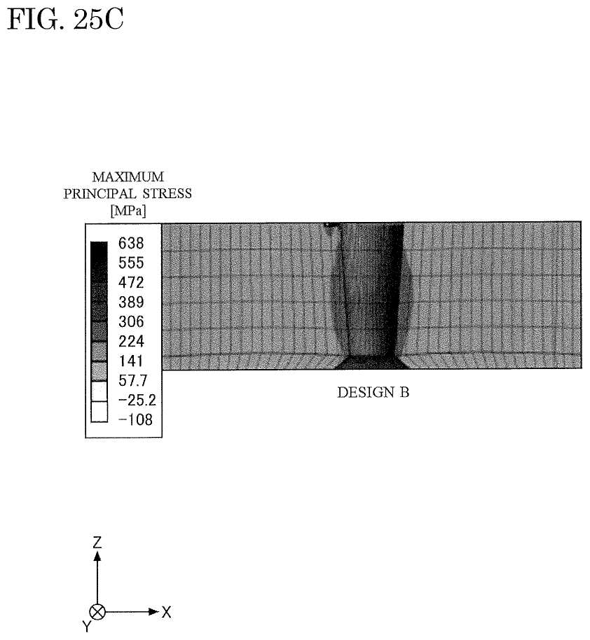

The simulation results are depicted in FIGS. 25A to 25C. FIG. 25A is a simulation result of stress in a top view of the ceramic plate 1 based on “Design 1”. FIG. 25A corresponds to FIG. 24A. This showed that the stress was slightly higher around the component number (1).

FIG. 25B is a simulation result of stress in a cross-sectional view of the ceramic plate 1 based on “Design 1”. FIG. 25B corresponds to FIG. 24C. FIG. 25C is a simulation result of stress in a cross-sectional view of the ceramic plate 1 based on “Design 2”. FIG. 25C corresponds to FIGS. 24D and 24E. In FIGS. 25B and 25C, the second conductive member 7b based on the second conductive paste 19 has a common structure regardless of the shape of the first conductive member 7a, and therefore is omitted in FIGS. 25B and 25C.

In FIG. 25B, the highest stress was found in the vicinity of the through hole 2 in the second surface 1b, that is, in a portion of the ceramic plate 1 defining the second opening 4 of the through hole 2 in the second surface 1b. In contrast, from the comparison between FIGS. 25B and 25C, it was found that the stress applied to the portion of the ceramic plate 1 defining the second opening 4 of the through hole 2 in the second surface 1b was reduced because the cross-sectional shape on the second surface 1b was a tapered shape in which the opening diameter decreases from the second surface 1b gradually in the thickness direction of the ceramic plate 1 by S33 of blasting in Design 2.

Further, as described above, the second conductive member 7b based on the second conductive paste 19 is omitted in FIGS. 25B and 25C.

However, actually, the second conductive member 7b based on the second conductive paste 19 was present on the first surface 1a and the second surface 1b.

Thus, in FIG. 25C, because the first opening 3 in the first surface 1a did not have a tapered shape differently from the second opening 4 in the second surface 1b, the stress was highest in the vicinity of the through hole 2 in the first surface 1a, that is, in the portion of the ceramic plate 1 defining the first opening 3 of the through hole 2 in the first surface 1a.

The results of the simulation in Evaluation 2 were consistent with the part where cracking has occurred in Evaluation 1.

As described above, the present invention has been described based on the specific embodiments, but these embodiments are merely presented as examples, and the present invention is not limited to the above-described embodiments. The embodiments described above can be implemented in various other forms, and various combinations, omissions, substitutions, additions, modifications, and the like can be made without departing from the spirit of the invention. These embodiments and variations thereof are included in the scope and spirit of the invention and are within the scope of the invention described in the claims and equivalents thereof.

What is claimed is:

1. A method for manufacturing a ceramic substrate, the method comprising:
preparing a ceramic plate having a first surface and a second surface on a side opposite to the first surface, the ceramic plate comprising a through hole that connects the first surface and the second surface, the through hole having a first opening formed in the first surface and a second opening formed in the second surface, a maximum diameter B1 of the second opening being less than 0.90 times a maximum diameter A1 of the first opening;
bringing into contact an inner surface, defining the through hole, of the ceramic plate and an etchant;
blasting the through hole from the second surface side;
disposing a first conductive paste in the through hole having been subjected to the blasting; and
sintering the first conductive paste.

2. The method for manufacturing a ceramic substrate according to claim 1, wherein, in the preparing, the through hole is formed in the ceramic plate by irradiating the ceramic plate with a laser from the first surface toward the second surface.

3. The method for manufacturing a ceramic substrate according to claim 1, wherein, in the preparing, the ceramic plate contains aluminum nitride.

4. The method for manufacturing a ceramic substrate according to claim 1, wherein, in the preparing, the ceramic plate is a sintered ceramic plate.

5. The method for manufacturing a ceramic substrate according to claim 1, wherein, in the bringing into contact, the etchant contains, as a pH adjusting agent, an alkaline solution containing one or more types selected from a group consisting of potassium hydroxide, sodium hydroxide, lithium hydroxide, calcium hydroxide, and magnesium hydroxide.

6. The method for manufacturing a ceramic substrate according to claim 1, wherein, in the bringing into contact, the etchant contains, as a pH adjusting agent, an acid solution of one or more types selected from a group consisting of hydrochloric acid, sulfuric acid, phosphoric acid, citric acid, and acetic acid.

7. The method for manufacturing a ceramic substrate according to claim 1, wherein the blasting further comprises blasting the through hole from the first surface.

8. The method for manufacturing a ceramic substrate according to claim 1, wherein C1>C2>C3 is satisfied, A2>C1 is satisfied, and B2>C3 is satisfied, where after the blasting,
a maximum diameter of a first opening of the through hole is defined as A2, the first opening being formed in the first surface,
a maximum diameter of a second opening of the through hole is defined as B2, the second opening being formed in the second surface, and
an average length between the first surface and the second surface is defined as L, and where
a maximum diameter of the through hole in a cross section in a direction substantially orthogonal to a thickness direction of the ceramic substrate at a location of L/4 from the first surface is defined as C1, a maximum diameter of the through hole in a cross section in a direction substantially orthogonal to the thickness direction of the ceramic substrate at a location of L/2 from the first surface is defined as C2, and a maximum diameter of the through hole in a cross section in a direction substantially orthogonal to the thickness direction of the ceramic substrate at a location of 3L/4 from the first surface is defined as C3.

9. The method for manufacturing a ceramic substrate according to claim 1, wherein, in the disposing of the first conductive paste, the first conductive paste is an active metal brazing material.

10. The method for manufacturing a ceramic substrate according to claim 9, wherein the active metal brazing material contains a eutectic powder of silver and copper, an active metal powder, and a solvent.

11. The method for manufacturing a ceramic substrate according to claim 10, wherein the active metal brazing material further contains at least one type of powder selected from a group consisting of a copper powder, a silver powder, a powder of an alloy of silver and copper, and a ceramic powder.

12. The method for manufacturing a ceramic substrate according to claim 10, wherein a content of the active metal powder in the active metal brazing material is in a range of 2 mass % to 15 mass %.

13. The method for manufacturing a ceramic substrate according to claim 1, further comprising, after the disposing of the first conductive paste and before the sintering:
disposing a first covering member on the first surface;
disposing a second covering member on the second surface; and
disposing a second conductive paste on a surface of the first conductive paste.

14. The method for manufacturing a ceramic substrate according to claim 13, wherein, in the disposing of the second conductive paste, the second conductive paste is an active metal brazing material.

15. The method for manufacturing a ceramic substrate according to claim 13, wherein, in the sintering after the disposing of the second conductive paste, the second conductive paste is sintered simultaneously with the first conductive paste.

16. The method for manufacturing a ceramic substrate according to claim 1, wherein, in the sintering, the sintering is performed at a temperature in a range of 700° C. to 1200° C.

17. The method for manufacturing a ceramic substrate according to claim 15, further comprising, after the sintering:
polishing or grinding the first covering member, the second covering member, and a conductive member that is formed by the sintering the first conductive paste and the second conductive paste, so as to expose the first surface and the second surface of the ceramic plate at a portion covered with the first covering member, the second covering member, and the conductive member.

18. A method for manufacturing a light-emitting device, the method comprising:
preparing the ceramic substrate manufactured by the method for manufacturing a ceramic substrate according claim 1; and
disposing a light-emitting element, comprising an electrode, on the ceramic substrate.

19. A ceramic substrate comprising:
a ceramic plate having a first surface and a second surface on a side opposite to the first surface, the ceramic plate comprising a through hole that connects the first surface and the second surface; and
a conductive member disposed inside the through hole, wherein C1> C2>C3 is satisfied, A2>C1 is satisfied, and B2>C3 is satisfied, where
a maximum diameter of a first opening of the through hole is defined as A2, the first opening being formed in the first surface,
a maximum diameter of a second opening of the through hole is defined as B2, the second opening being formed in the second surface, and
an average length between the first surface and the second surface is defined as L, and where a maximum diameter of the through hole in a cross section in a direction substantially orthogonal to a thickness direction of the ceramic substrate at a location of L/4 from the first surface at a location L1 is defined as C1, a maximum diameter of the through hole in a cross section in a direction substantially orthogonal to the thickness direction of the ceramic substrate at a location of L/2 from the first surface at a location L2 is defined as C2, and a maximum diameter of the through hole in a cross section in a direction substantially orthogonal to the thickness direction of the ceramic substrate at a location of 3L/4 from the first surface at a location L3 is defined as C3.

20. The ceramic substrate according to claim 19, wherein a maximum diameter of the through hole when the maximum diameter of the through hole in a cross section in the direction substantially orthogonal to the thickness direction of the ceramic substrate is smallest between the second surface and the location L3 is defined as C4, the average length Lis 2.5 times or more the maximum diameter C4.

21. The ceramic substrate according to claim 19, wherein the maximum diameter A2 is in a range of 120 μm to 300 μm, and the maximum diameter B2 is in a range of 100 μm to 280 μm.

22. The ceramic substrate according to claim 19, wherein the average length Lis in a range of 200 μm to 600 μm.

23. The ceramic substrate according to claim 19, wherein, in a cross-sectional view in the thickness direction of the ceramic substrate,
an interior angle R1 is smaller than 90 degrees, the interior angle R1 being an angle formed at a side of the through hole at an intersection point between the second surface and an imaginary line V1, which passes through a point of contact M1 between the second surface and an inner surface defining the through hole and is an extension of a portion, extending from the second surface, of the inner surface defining the through hole in the cross-sectional view in the thickness direction of the ceramic substrate, and
an exterior angle R2 is larger than 90 degrees, the exterior angle R2 being an angle formed at a side opposite to the through hole at an intersection point between the imaginary line V1 and an imaginary line V2, which passes through location L2 and location L3 on the inner surface defining the through hole, in the cross-sectional view in the thickness direction of the ceramic substrate.

24. The ceramic substrate according to claim 19, wherein, in a cross-sectional view in the thickness direction of the ceramic substrate,
an interior angle R3 is smaller than 90 degrees, the interior angle R3 being an angle formed at a side of the through hole at an intersection point between the first surface and an imaginary line V3, which passes through a point of contact M2 between the first surface and an inner surface defining the through hole and is an extension of a portion, extending from the first surface, of the inner surface defining the through hole in the cross-sectional view in the thickness direction of the ceramic substrate, and
an exterior angle R4 is larger than 90 degrees, the exterior angle R4 being an angle formed at a side opposite to the through hole at an intersection point between the imaginary line V3 and an imaginary line V4, which passes through location L2 and location L1 on the inner surface defining the through hole in the cross-sectional view in the thickness direction of the ceramic substrate.

25. The ceramic substrate according to claim 19, wherein an arithmetic mean roughness Ra of an inner surface defining the through hole is in a range of 0.5 μm to 2.0 μm.

26. A light-emitting device comprising:
the ceramic substrate according to claim 19; and
a light-emitting element comprising an electrode, and disposed on the ceramic substrate.
